(19) United States
(12) Patent Application Publication
(10) Pub. No.: US 2012/0038031 A1
(43) Pub. Date: Feb. 16, 2012

(54) DISPENSING LIQUID CONTAINING MATERIAL TO PATTERNED SURFACES USING A DISPENSING TUBE

(75) Inventors: Emanuel M. Sachs, Newton, MA (US); Richard L. Wallace, Acton, MA (US); James F. Bredt, Watertown, MA (US); Benjamin F. Polito, Gorham, ME (US); Ali Ersen, Chestnut Hill, MA (US)

(73) Assignee: 1366 TECHNOLOGIES INC., Lexington, MA (US)

(21) Appl. No.: 13/142,472

(22) PCT Filed: Jan. 6, 2010
(86) PCT No.: PCT/US2010/020245

§ 371 Date: Nov. 2, 2011

Related U.S. Application Data
(60) Provisional application No. 61/204,382, filed on Jan. 6, 2009.

(51) Int. Cl. H01L 23/544; B65D 35/38

(52) U.S. Cl. 257/622; 222/566; 257/E23.179

(57) ABSTRACT

Materials that contain liquid are deposited into grooves upon a surface of a work piece, such as a silicon wafer to form a solar cell. Liquid can be dispensed into work piece paths, such as grooves under pressure through a dispensing tube. The tube mechanically tracks in the groove. The tube may be small and rest at the groove bottom, with the sidewalls providing restraint. Or it may be larger and ride on the top edges of the groove. A tracking feature, such as a protrusion, Non-circular cross-sections, molded-on protrusions and lobes also enhance tracking. The tube may be forced against the groove by spring or magnetic loading. Alignment guides, such as lead-in features may guide the tube into the groove. Restoring features along the path may restore a wayward tube. Many tubes may be used. Many work pieces can be treated in a line or on a drum.

### RELATED DOCUMENT

Priority is hereby claimed to U.S. Provisional application Ser. No. 61/204,382, entitled DISPENSING LIQUID CONTAINING MATERIAL TO PATTERNED SURFACES USING A CAPILLARY DISPENSING TUBE, in the names of Emanuel M. Sachs, Richard L. Wallace, James F. Bredt and Benjamin F. Polito, filed on Jan. 6, 2009, which is hereby incorporated herein fully by reference.

### BACKGROUND

Certain processing schemes and architecture are disclosed in Patent Cooperation Treaty Application No: PCT/US2008/002058, entitled, SOLAR CELL WITH TEXTURED SURFACES, Filed: Feb. 15, 2008, in the names of Emanuel M. Sachs and James F. Bredt and The Massachusetts Institute of Technology, designating the United States of America, and also claiming priority to two provisional United States applications, No. U.S. 60/901,511, filed Feb. 15, 2007, and No. U.S. 61/011,933, filed Jan. 23, 2008. All of the PCT application and the two US provisional applications are hereby incorporated fully herein by reference. The technology disclosed in these applications is referred to herein collectively as Self Aligned Cell (SAC) technology.

It is desired to be able to precisely treat material that contains liquid onto textured work pieces such as are described in the above referenced patent applications. It is also desired to be able to so treat such material at relatively high rates of speed, using a wide variety of materials to be treated, into narrow grooves, or along narrow paths defined by the texture of the work piece.

### BRIEF SUMMARY

Liquids, slurries and pastes and other of materials that contain liquid are deposited into grooves or along other physical work piece paths upon a surface of a work piece, such as a silicon wafer that will be used to form a solar collecting cell. Liquid can be dispensed into grooves in which will be formed thin metallization finger elements, under pressure through a fine dispensing capillary tube, which is mechanically guided and aligned by following topography/surface texture on the work piece surface. The dispensing capillary tube mechanically tracks in the groove. The dispensing capillary may be small enough that it rests at the groove bottom, with the groove sidewalls providing tracking restraint. Or, the dispensing capillary may be larger than the groove and may ride on the top edges of the groove, still achieving mechanical alignment. A tracking feature, such as a protrusion, may be provided at the dispensing end to engage the groove. Non-circular cross-sections and other tracking features, such as elliptical, molded-on protrusions and lobes can enhance tracking in a groove. The dispensing capillary tube is typically flexible. The flexibility accommodates tracking errors in both the plane of the work piece, generally perpendicular to the elongated dimension of the work piece path and perpendicular to that plane, which errors are due to differences between the physical work piece path on the work piece, and the unconstrained path that the dispensing end of the tube would follow, were it allowed to travel along a perfectly flat, frictionless work piece. The errors are due to errors in machining the physical work piece path, errors in directing a relative motion device to follow a mathematical representation of the work piece path, errors in manufacturing the dispensing tube and other apparatus, such that the model of its trajectory is inaccurate, etc. Rather than using a flexible tube, a tube that is supported by a pivot that pivots in both the directions of perpendicular to the plane of the work piece and within the plane of the work piece. The dispensing capillary is typically further held to the groove by the capillary action of the dispensed liquid itself. The dispensing capillary may be forced against the groove, such as by spring or magnetic loading. Alignment guides, such as lead-in features may guide the dispensing capillary into the groove. Restoring features along the length of the work piece path may help restore a wayward dispensing tube back to the groove. A multiplicity of dispensing capillaries may be used, each dispensing in a separate groove for an individual finger. A number of wafers can be treated in a line. Time spent accelerating and decelerating at the beginning and end of travel is reduced. A plurality of wafers may be disposed on faces of a drum with flats and, with the drum rotating continuously. The dispensing capillary tube can be traversed parallel to the drum axis while moving in and out to provide rise and fall as an individual wafer is traversed.

These and other objects and aspects of inventions disclosed herein will be better understood with reference to the Figures of the Drawing, of which:

### BRIEF DESCRIPTION OF THE FIGURES OF THE DRAWING

FIG. 1 is a schematic representation of a textured photovoltaic device, bearing grooves that carry metallization fingers, as described herein;

FIG. 2 is a schematic representation showing a dispensing capillary tube resting on the bottom surface of a groove;

FIG. 2A is an enlargement of the region A of FIG. 2;

FIG. 3 is a schematic representation of a dispensing capillary tube with a circular cross section of a diameter that is larger than the width of the grooves into which material is being dispensed;

FIG. 3A is an enlargement of the region A of FIG. 3;

FIG. 4 is a schematic representation showing a dispensing capillary tube being held in the groove in part by capillary action of the dispensed liquid itself;

FIG. 5A is a schematic representation showing a dispensing capillary tube approaching a groove that has a triangular lead-in feature alignment guide;

FIG. 5B is a schematic representation showing a groove that has a lead-in feature alignment guide composed of two angled grooves that meet at the groove end;

FIG. 6 shows schematically a capillary dispensing tube having an elliptical cross-section;

FIG. 7 shows schematically a capillary dispensing tube having a circular cross-section, cut with a bevel edge;

FIG. 8 shows, schematically, a capillary dispensing tube traversing a groove with spaced apart angled alignment guiding restoring features to help return an errant dispensing tube to the desired path;

FIG. 9, in two sub-parts, 9A, 9B, shows, schematically, work piece surface restoring feature patterns that will aid in guiding a dispensing capillary tube along an intended work piece path, with FIG. 9A, showing no groove for the intended work piece path and FIG. 9B, showing a groove;

FIG. 10 shows schematically a dispensing apparatus having a plurality of dispensing capillary tubes which move together;

FIG. 10A is an enlargement of the portion shown at A in FIG. 10;

FIG. 11 shows schematically a rotary apparatus, having a plurality of work pieces for deposit, arranged around the periphery of a drum, and a single capillary dispensing tube engaging a groove of the work piece;

FIG. 11A shows schematically an enlargement of a portion of FIG. 11, at A;

FIG. 12 shows, schematically, a metallization finger in a serpentine pattern having a single dispensing capillary tube;

FIG. 13 shows, schematically, an arrangement where edges of a work piece beyond the ends of the work piece path groove are masked with a thin layer of material to prevent dispensed liquid from touching the edge of the work piece even though the dispensing capillary is dragged across the edge regions, and also showing a cleansing bath; and

FIG. 14 shows, schematically, a work piece having a metallization finger channel that has a width that varies along its length, which channel can be treated with material dispensed according to inventions hereof;

FIG. 15 shows, schematically, a flexed capillary dispensing tube dispensing material that contains liquid in a groove on a work piece with a hexagonal array of pits;

FIG. 16 shows, in block diagram form, concepts that are useful to understand alignment and tracking accuracy issues;

FIG. 17 shows schematically, a flexed capillary dispensing tube with a tracking feature, on a work piece with a hexagonal array of pits;

FIG. 18 shows, schematically, a capillary tube carrying a tracking feature having a rounded face, at one location, near the dispensing end;

FIG. 19 shows, schematically, a flexed capillary dispensing tube with a tracking feature having magnetic particles, on a work piece with a hexagonal array of pits supported by a metal plate attracted to the magnetic particles;

FIGS. 20A-20D show a sequence illustrating schematically a capillary dispensing tube moving bi-directionally, with its support end maintained relatively perpendicular to the plane of the work piece, vertical as shown;

FIGS. 21A-21D show a sequence illustrating schematically a capillary dispensing tube moving bi-directionally, with its support end being rotated through perpendicular to the work piece, from one pass to another;

FIG. 22 shows schematically, a capillary tube carrying a flat faced tracking feature at one location;

FIG. 23 shows schematically, a capillary tube carrying a tracking feature made by adhering a wire to the end of a tube at one location;

FIG. 24 shows schematically, a capillary tube carrying a tracking feature having a rounded face, at two locations, along a substantial length of the dispensing tube;

FIG. 25 shows, schematically, a capillary tube carrying a tracking feature having a flat face, at two location, near the dispensing end of the tube;

FIG. 26 shows, schematically, a flexed capillary dispensing tube dispensing material that contains liquid in a groove on a work piece with a hexagonal array of pits, where the grooves are arranged in groups of three side-by-side grooves;

FIG. 27 shows schematically an apparatus for dispensing material that contains liquid through capillary dispensing tubes, showing three ranks of three dispensing tubes, arranged to treat material to work pieces that pass by the ranks along a conveying apparatus;

FIG. 27A shows an end view of the apparatus shown in FIG. 27

FIG. 27B shows a plan view of the apparatus shown in FIG. 27;

FIG. 28 shows, schematically, a relatively inflexible capillary dispensing tube that is supported by a ball and socket joint;

FIG. 29A shows, schematically, in a plan view, a capillary dispensing tube that has a crimp near to its support end, affording flexibility to an otherwise relatively inflexible tube;

FIG. 29B shows, schematically, in an elevation view, the crimped capillary dispensing tube shown in FIG. 29A; and

FIG. 30 shows, schematically, an apparatus having a flexible positioning element that is a different physical element from the fluid dispensing element.

### DETAILED DESCRIPTION

Inventions disclosed herein relate to applying liquids, slurries and pastes and other similar forms of material that bears a liquid, into grooves (or similar structures) upon a surface of a work piece. The inventions are especially relevant to forming thin metallization elements on photovoltaic absorbers, generally referred to as fingers as generally described in the above referenced PCT application, PCT/US2008/002058. This applying liquids, slurries pastes, etc., is referred to generally as treating herein, as well as in the above referenced PCT application. According to inventions disclosed herein, liquid is dispensed and metered in a potentially precisely controlled fashion, under pressure through a fine dispensing capillary tube, which is mechanically guided and aligned by following topography/surface texture on the surface of the work piece. In one embodiment, the work piece is a silicon wafer that has grooves in it for metallization.

The above referenced PCT application discusses treating a work piece, by which it is meant applying a liquid that is typically associated with an active, typically reactive treating step, which the user desires should take place at certain zones of the work piece, such as plating or etching. The work piece is textured such that the liquid can be applied in a portion of a zone comprised of a network of liquid accessible pathways. The application of liquid is guided at least in part by the texture. The liquid remains excluded from flowing into zones that the designer intends the treating step to not take place. The exclusion arises due, at least in part, to the surface texture. An example of such a treating is described in the PCT application for providing electrodes to the PV cell surface. The techniques disclosed herein are predominantly for such treating applications.

Inventions disclosed herein may be used for dispensing materials that are active, typically reactive, for a treating step, and also for materials that could be used for blocking a subsequent active, reactive step. Thus, they are referred to generally as dispensing techniques.

The dispensed material may be a silver ink of the same general composition as those used in the manufacture of silicon solar cells and typically applied by screen printing. A particularly advantageous method is to dispense only a small quantity of such ink so as to result in only a thin layer of metal after firing of the work piece. While this thin seed layer is itself not sufficient to carry the current generated by the solar cell, it may then be built up by plating, for example of silver. The plated metal tends to be confined to the groove and builds up vertically, but does not spread much horizontally. The silver ink used for the seed layer may be more dilute in solids loading than a conventional silver paste as only a seed layer is needed.

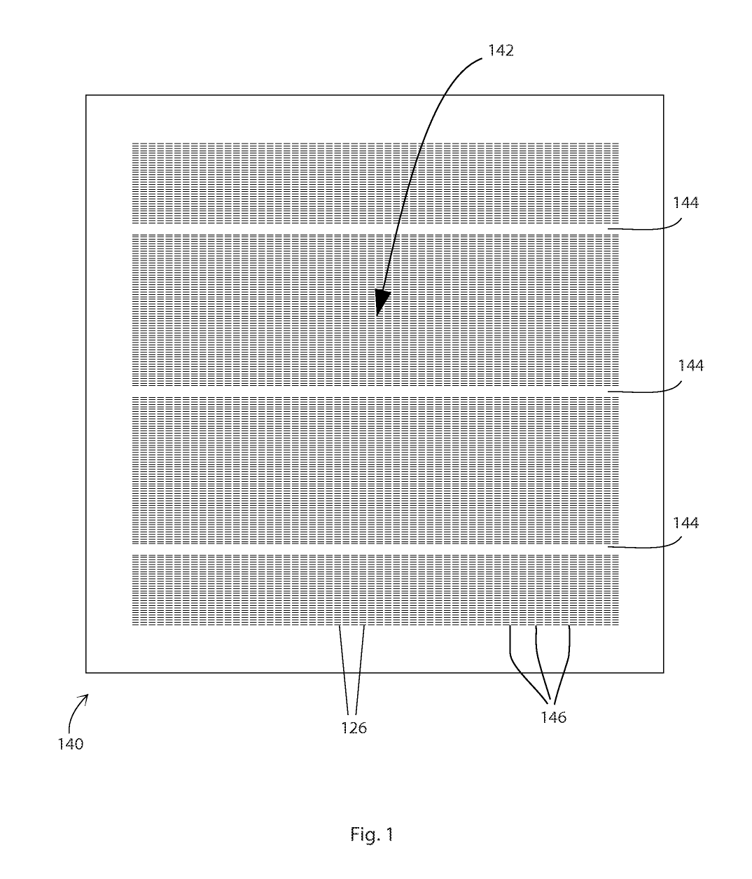

As shown schematically with reference to FIG. 1, solar cell 140, has a textured surface 142. Grooves for light trapping purposes 126 run across the cell face, from left to right, as shown. Bus wires 144 run parallel to the grooves 126. Metallization fingers 146 intersect with the bus wire 144, and run perpendicular to the texture grooves 126. Inventions disclosed herein are useful for many applications related to treating materials to different regions of a textured work piece that will be used to form such a solar cell. They are particularly suited for dispensing materials into grooves (or similar structures) that will be metalized to provide the metallization fingers 146.

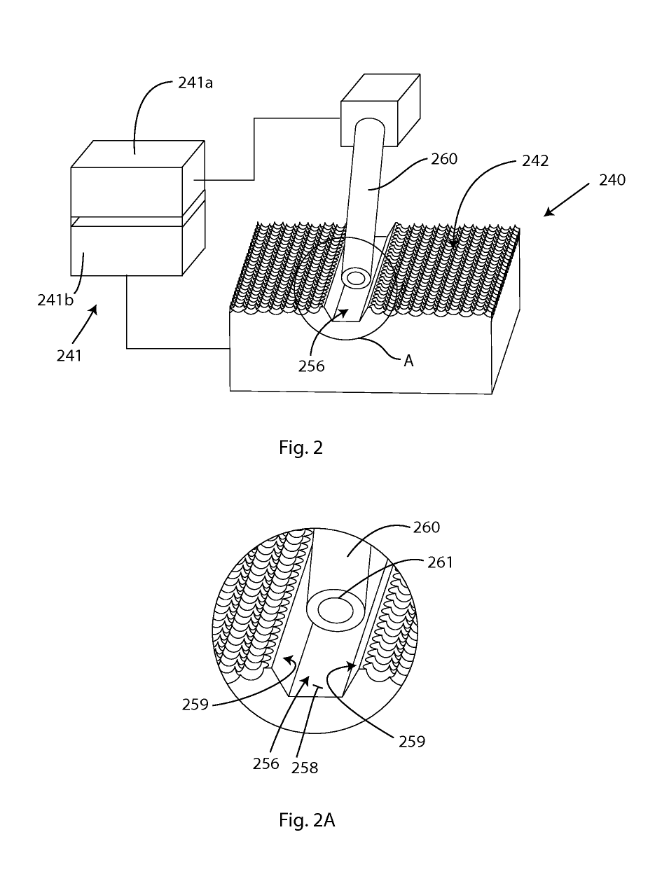

FIG. 2 shows, schematically, an enlarged portion of a work piece 240, such as a silicon wafer that will become part of a solar cell such as 140. The textured surface 242 is textured with adjacent, overlapping portions of hemispheres, rather than parallel light trapping grooves as discussed above and shown in FIG. 1. The work piece is supported appropriately by any support, such as a stage, a chuck, or other apparatus (not shown). An enlarged view of a portion of a groove 256, (different from a light trapping groove) such as would be used for metallization fingers 146 is shown in FIG. 2A.

The dispensing capillary tube 260 is caused to move relative to the groove 256 in the work piece 240, as material that contains liquid is dispensed from the tube. The relative motion is provided by any suitable relative motion device 241, shown schematically, which is coupled to both the dispensing capillary tube 260 and the work piece 240 through the work piece support, in such a way that the work piece 240 and the dispensing capillary tube 260 may be moved and rotated relative to each other as needed, for instance through all six degrees of freedom. (It may be that fewer than all six degrees of freedom are used, but they can be.) In a common arrangement, there will be two degrees of freedom of relative translational motion between the capillary dispensing tube and the work piece and zero or one degree of freedom of relative rotational motion. Typically, the relative motion device 241 has two portions, 241a and 241b, which move relative to each other. (As used herein the term move means to translate and/or rotate, and the term motion as used herein means translation and/or rotation.) The relative motion drive mechanism may be configured with a stationary work piece (relative to ground) and a capillary dispensing tube support apparatus that moves relative thereto, or, alternatively, a stationary capillary dispensing tube support apparatus (relative to ground) and a work piece that moves relative thereto, or a combination of both relative motions, where both the capillary dispensing tube support apparatus and the work piece move relative to ground. Although it is mentioned that the relative motion device 240 generally has two portions that move relative to each other, each of these portions, 241a, 241b may itself be highly complicated, and be composed of many parts that move relative to each other.

Mechanical guidance of the dispensing capillary tube 260 is accomplished by at least two mechanisms, both of which involve interaction with the groove 256 and both of which typically contribute an effect. This embodiment will be used to illustrate the general principal.

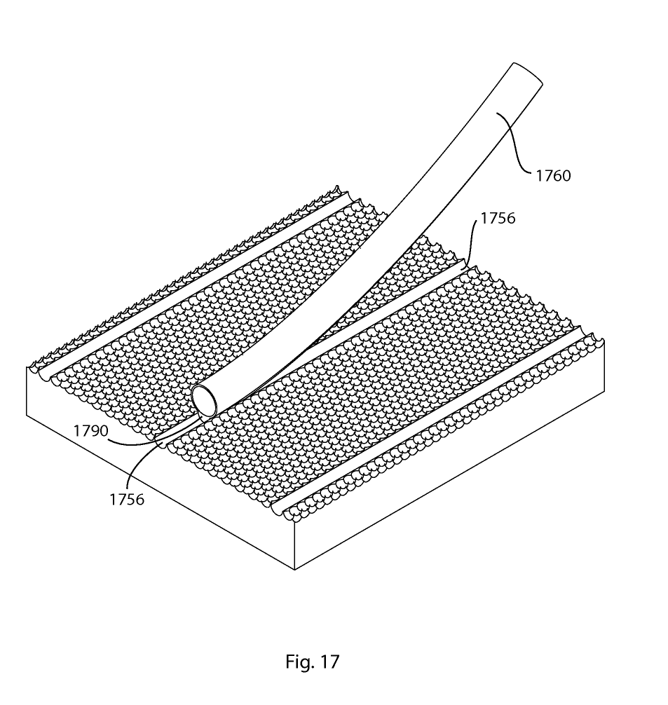

According to one guidance mechanism, as shown in FIGS. 2 and 2A, the dispensing capillary tube 260 mechanically tracks in the groove, much like a phonograph needle in an audio record popularly in use before the advent of magnetic and digital media. In some cases, as shown in FIG. 2A, the dispensing capillary tube 260 is small enough that it rests on the bottom 258 of the groove and the sidewalls 259 of the groove provide for tracking as shown in FIG. 2A. The grooves may be various shapes, including semi-cylindrical, as shown in FIG. 17.

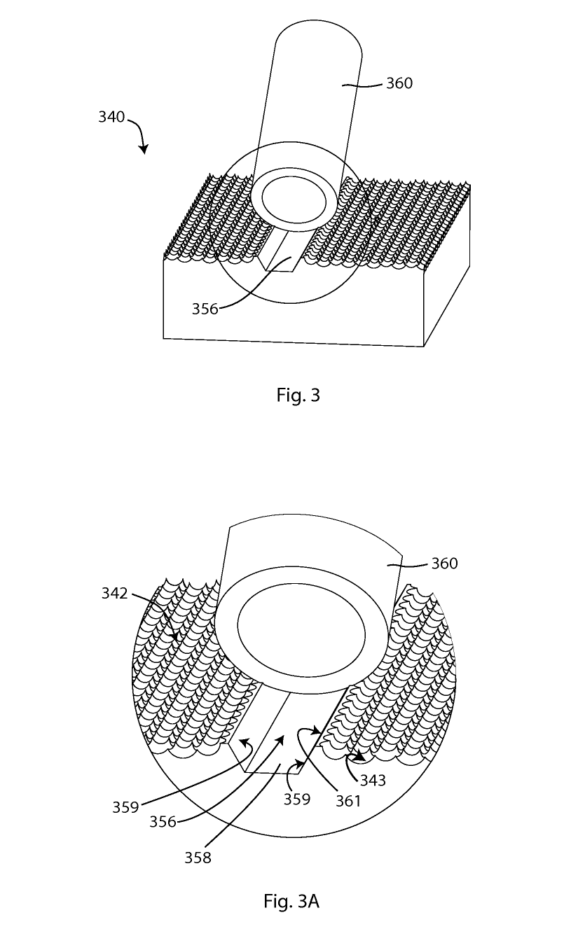

In other cases, as shown in FIGS. 3 and 3A, the dispensing capillary tube 360 is larger than the dimension of the treated groove 356 and therefore rides on the top edges 361 of the groove, still achieving mechanical alignment. FIG. 3 shows a dispensing capillary tube 360 with circular cross section of a diameter which is larger than the width of the grooves 356 in the wafer being treated.

Thus, in this regard, the dispensing capillary tube is sized to mechanically track a path defined by the textured work piece surface. At one end of a range of appropriate sizing, such as shown in FIG. 2A, a simple cylinder with no additional tracking feature (as defined below), has a small enough diameter relative to the groove width, such that the tube itself fits fully within the width of the groove. Such a tube is thus sized to mechanically track the path. (In some cases, such a relatively small tube may have troubles with clogging, but in some cases, it may be operated without clogs, and is thus, useful. Whether clogging is a problem primarily depends on the nature of the material being treated. If the material that contains liquid also has particles—such as a silver particle ink, then a small diameter capillary may present a challenge. If no particles are present, then small diameter capillary dispensing tubes are ordinarily not a challenge to operate.)

At another end of the range of being so sized to mechanically track, is a tube that is several times larger in diameter than the groove width (generally up to approximately ten times larger), which may also be considered appropriately sized to mechanically track the path. Such a larger tube may be a simple cylinder, as shown in FIG. 3A. But, an additional tracking feature may be provided, described more fully below. FIG. 3A is not drawn to scale, but it is meant to represent a situation that illustrates the upper end of the range, of a tube that has a diameter that is approximately ten times the width of the groove in the groove to be treated.

Thus, both of the tubes shown in FIGS. 2A and 3A are sized and shaped to mechanically track the grooves shown associated with them, respectively, as would all tubes having a diameter of greater than that shown in FIG. 2A, and less than that shown in FIG. 3A (representing a tube that is approximately ten times the width of the groove), as compared to the width of the groove.

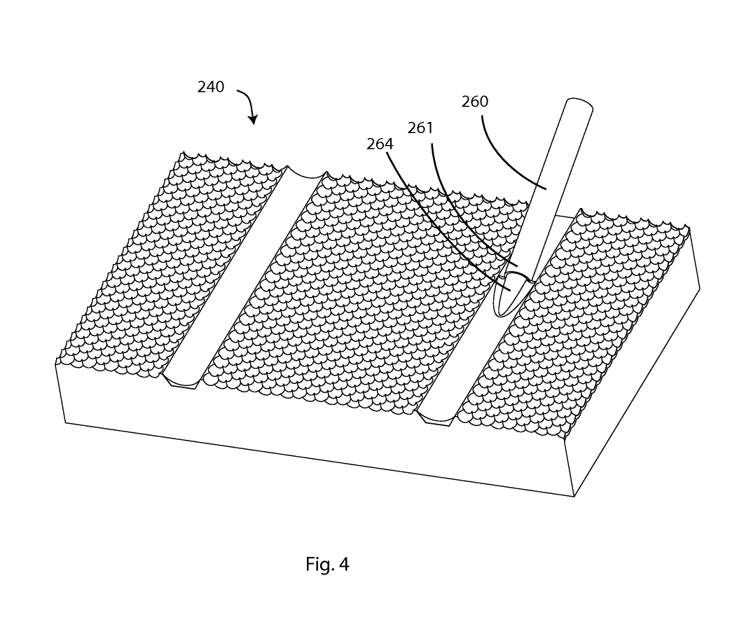

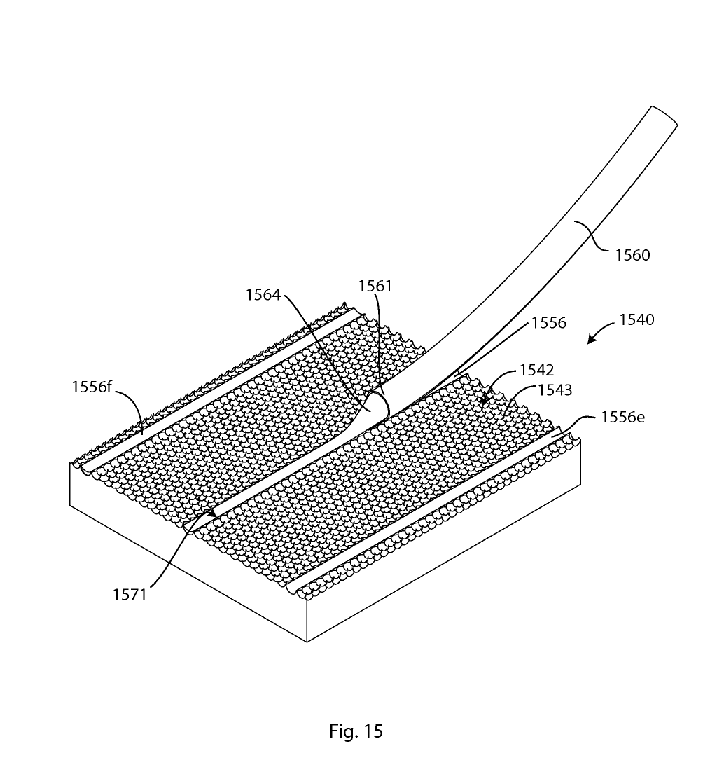

According to a second guidance mechanism, as shown schematically with reference to FIGS. 4 and 15, the dispensing capillary tube 260, 1560 is further held to the groove by the capillary action of the dispensed liquid 264, 1564 itself, which bridges between the dispensing tube 260, 1560 dispensing end 261, 1561 and the work piece 240, 1540.

While the relative motion of the tube and the work piece can be controlled to keep the dispensing end 261 of the tube near to the groove that is the desired path for the tube to follow, manufacturing variations and machine accuracy will cause the path that an unconstrained dispensing tube would follow, to deviate from the physical path, such as a groove, in the work piece. The flexibility of the tube allows for lateral and vertical deflections so that the tube tracks in the groove, even if there is not perfect alignment, as formalized below.

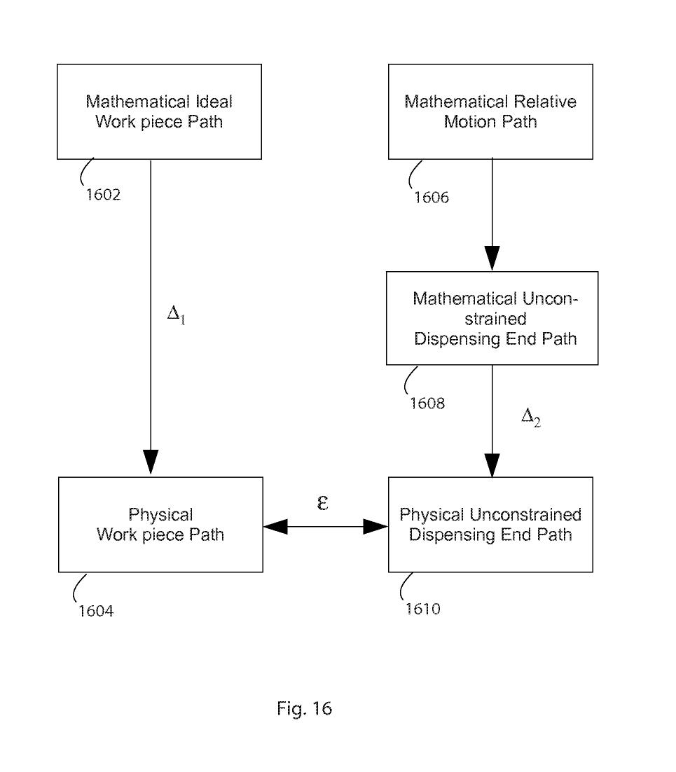

This is more fully understood with reference to FIG. 16. The designer establishes a mathematical, ideal work piece path 1602, along which it is desired to provide the material that contains the liquid, for instance to establish a metallization groove on a semi-conductor wafer. A physical work piece path 1604, for instance a groove, is established on the work piece surface, for instance by etching, laser machining, or other techniques described more fully below. Typically, there will be an error Δ₁, by which the physical work piece path 1604 deviates from the ideal mathematical work piece path 1602. For instance, the groove-making technique will typically have distortions, scale errors, and other positional accuracy limitations, and there will similarly be a finite tolerance associated with the placement of the work piece on the physical relative motion drive mechanism.

The relative motion drive mechanism 241 as shown schematically with reference to FIG. 2 is programmed or otherwise configured and controlled to follow a mathematical relative motion path 1606. The mathematical relative motion path 1606 is designed with the intent to take into account the geometry of the dispensing capillary tube, the physical work piece path, actuated rotation of the tube for reversal of direction, the speed of relative motion between the two, etc., so that the dispensing end 261 of the dispensing capillary tube 260 will follow a mathematical unconstrained dispensing end path 1608 which matches exactly the mathematical work piece path 1602, for instance a mathematical representation of a groove 256. As used herein, unconstrained means, the path that the dispensing end 261 would travel if it were permitted to contact and move along a perfectly flat and frictionless work piece (including flexing from pre-loading, as discussed above).

However, there are many sources of error which will cause the physical unconstrained dispensing end path 1610 to deviate from the mathematical unconstrained dispensing end path 1608 as captured by error Δ₂ in FIG. 16. For instance, the dispensing tube may not be perfectly straight, and the relative motion drive system will have limitations of band width, motor size, etc.

Because of the effect of the accumulation of the errors Δ₁ and Δ₂, the physical unconstrained dispensing end path 1610, deviates from the physical work piece path 1604 by an error E. This error E is accommodated by the flexibility of the capillary dispensing tube, allowing the dispensing end 261 of the dispensing tube to exactly track and follow the physical work piece path 1604. Typically, the error E may be manifested in lateral deviations between the unconstrained dispensing end path 1610 and the physical work piece path 1604, generally perpendicular to the elongated dimension of the physical work piece path and generally within the plane in which it generally resides. The error E may also be manifested in vertical deviations between the unconstrained dispensing end path 1610 and the physical work piece path 1604, for instance due to variation in the thickness of the work piece.

The length of the capillary tube may be chosen according to the maximum error E that is to be encountered. Thus, if the maximum error is 100 microns, the capillary may be relatively short—just a few mm long. However, if the maximum error is one mm, then a relatively longer capillary of at least 10 mm length would be more appropriate.

An important consideration is to prevent the angle of the tube at the dispensing end from assuming too high a value with respect to the groove itself, as a high angle will more easily lead to the tube riding up over the edge of the groove and escaping from the groove. For this reason, as the maximum anticipated error increases, the length of the tube should be increased proportionally. The proportionality between deflection and length for a given maximum angle of tube end with respect to the groove applies to the case of a tube or other structural member along which it rides that is flexed as a cantilever. The proportionally also applies to the case of a straight tube which is allowed to pivot at its support.

The operational parameters required to provide a desired degree of tolerance to misalignment between the unconstrained dispensing end path 1610 and the physical work piece path 1604, can be estimated by examining the mechanics of the tube in the groove. The side-walls of the grooves in the work piece can vary over a wide range from very shallow to very steep (perpendicular to the plane of the work piece). The maximum restoring force that can be exerted by the groove on the capillary before the capillary disengages from the groove will be approximately proportional to any downward force of the tube against the work piece as determined by a preload of the tube. The relative shape of the groove and capillary will change the constant of proportionally between a preload force and maximum restoring force. A useful estimate can be made by assuming the walls of the groove are at 45 degrees to the work piece and that there is no friction between the groove and tube. In this case, the maximum restoring force is approximately equal to any preload force. Note that this is only true for a tube with the same stiffness in vertical and horizontal directions.

Thus, mechanical tracking of a dispensing capillary tube in a groove is aided by having the dispensing capillary tube forced against the groove with a positive preload force. Any appropriate way to do this is considered within the bounds of inventions disclosed herein.

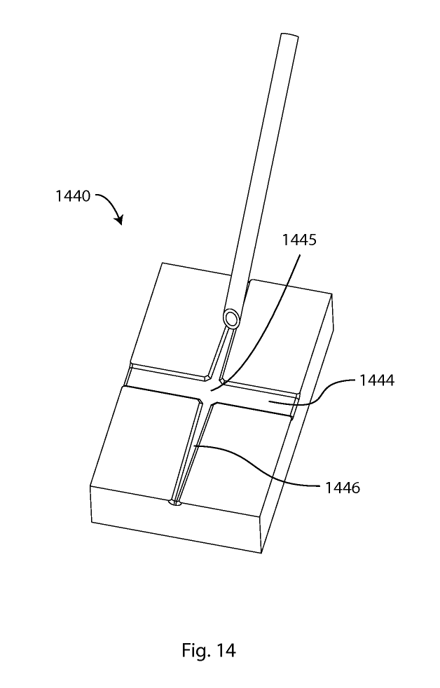

One way is to spring load the tube against the groove. Spring loading can be accomplished using the elasticity of the dispensing capillary tube 260 itself. For example, a suitable dispensing capillary tube may be made of polyimide tubing with an ID of 65 microns and an OD of 90 microns and a cantilevered length of 5 mm, which is adhered to the ID of a piece of stainless steel tube. The steel tube is secured in and supported by a support assembly. This dispensing capillary tube is disposed downward at an angle to the horizontal of typically 30 degrees. The spring pre-load is applied by lowering the dispensing capillary tube until it touches the work piece and then lowering the dispensing capillary tube support assembly another 1 mm, thus flexing the extended dispensing capillary tube. FIG. 14, (among others), shows schematically a flexed capillary dispensing tube 1460. The groove is typically 30-50 microns wide, although both smaller and larger widths are possible.

FIG. 10 shows a typical arrangement (for a multi-tube embodiment, discussed below), with a steel tube 1063, anchored in a support assembly 1065, and a polymeric dispensing tube 1060 extending from the steel tube 1063. It is also possible to use dispensing capillaries made of glass such as borosilicate. A polymeric dispensing tube has a high damping, which compares favorably with the damping of glass. Another suitable candidate is a quartz capillary tube, having an ID of 50 microns, and an OD of 80 microns. Metals may also be used, such as stainless steel. If needed, damping could be added to such structures by coating with a thin layer of a polymer. For capillaries of higher modulus materials such as glass or metal, the tube will have to be longer than would a polymeric tube in order to accommodate the same degree of error E. Capillary tubes may also be drawn down so that they have a larger diameter section which gradually reduced to a smaller diameter. Borosilicate glass, for example, can be drawn down in such a manner by methods known in the art. It is advantageous to have the dispensed material flow through a filter immediately before entering the capillary dispensing tube to avoid clogging of the tube. The filter should retain any particles that are larger than only a fraction of the internal diameter of the tube. For example, when using a tube with 100 micron ID, the filter should retain particles that are larger than 10 microns.

Following the discussion above regarding the relation between restoring forces and any downward force, if the tube is circular, the stiffness in the plane of the tube perpendicular to the work piece and in a plane parallel to the work piece are roughly equal. Hence, the maximum misalignment of the tube end from the groove will be approximately equal to the preload distance of the tube against the work piece, by which it is meant the difference in the spacing between the work piece and the dispensing end of the tube in a pre-loaded state, as compared to a relaxed, zero preload case.

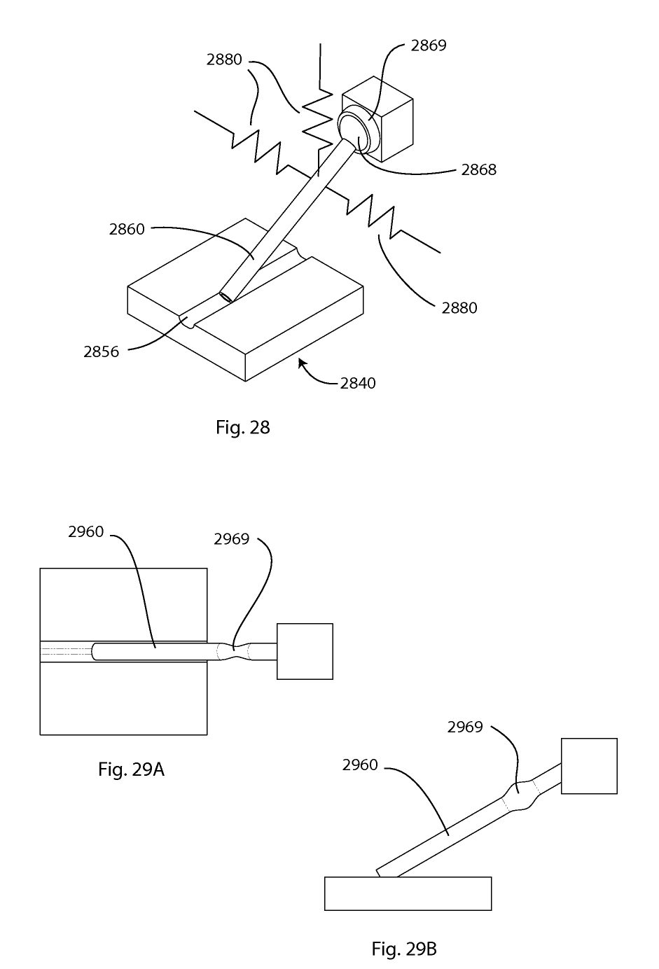

While it is convenient to use the inherent flexibility of the dispensing tube to provide the compliance that allows the dispensing tip to track the groove, other approaches are possible. For instance, with reference to FIG. 28, a fluid-tight pivoting ball-and-socket joint 2868, 2869 may be employed in conjunction with one or more elastic spring elements 2880 to provide the desired degree of compliance, allowing dispensing tube 2860 to track groove 2856. This approach has the advantage that the angle (in plan view) between the local axis of the dispense tip and the axis of the groove on the work piece will be smaller for a given degree of lateral offset than in the case where the compliance comes from the flexibility of the tube.

The above effect may be approximated by partially crimping the tube near its support end, as in FIGS. 29A and 29B. A dispensing tube 2960 has been plastically deformed near its support end to form an approximately elliptical crimped region 2969 characterized by locally decreased stiffness in the lateral direction. This has the effect of focusing the bending at a localized region near the support end, approximating the behavior of a pivot. It has the further effect of producing a dispensing tube with greater stiffness in the vertical direction in the horizontal direction, which may be beneficial as discussed elsewhere herein.

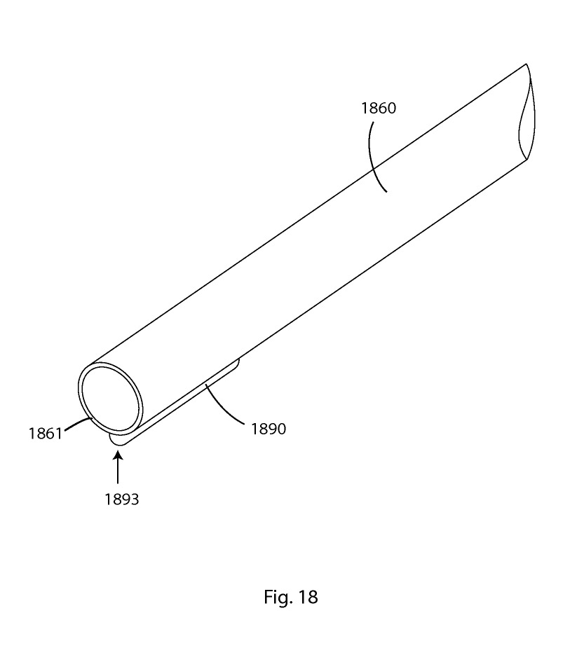

For reasons connected with establishing tracking, discussed below, as shown in FIG. 18, it may be beneficial to mold a feature 1890 onto a tube 1860. Such a feature may be fabricated of epoxy or another polymer adhesive, its shape provided by a silicone rubber mold against which the tube is disposed.

A useful option shown schematically with reference to FIG. 19 is to fill such a cast feature 1990 with particles of a material capable of permanent magnetization. For example, they could be of magnetic iron oxides or of rare earth magnet material such as particles of neodymium-iron-boron. After molding, this material could be poled so that the north-south axis is perpendicular to the axis of the dispensing tube 1960. This small permanent magnet could then be used to provide downward force on the capillary dispensing tube by placing a plate 1991 of ferromagnetic material—such as a plate of low carbon steel—under the work piece 1940. In this manner a high downward force could be exerted on the tube even without the need to spring pre-load the tube 1960. Of course, the magnetic preload could also be added to a mechanical spring preload to increase the tracking ability of the tube. If only a magnetic pre-load is present, the dispensing tube 1960 would likely bend with a concave curvature toward the work piece 1940, oppositely to that shown in FIG. 19.

While the capillary dispensing tube is shown disposed at a small angle with respect to the surface to be treated in most of the figures, such as FIGS. 2, 4 and 5, the angle of the tube may vary widely. It may be nearly parallel to the surface, on the one hand. On the other hand it can go all the way to perpendicular to the surface. Maintaining the tube perpendicular to the surface has the advantage that bi-directional dispensing can be performed without the need to rotate the support end of the tube relative to the work piece.

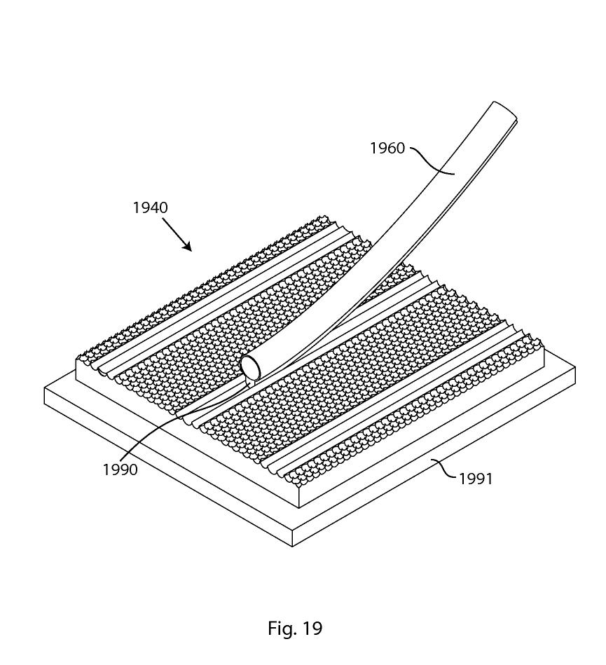

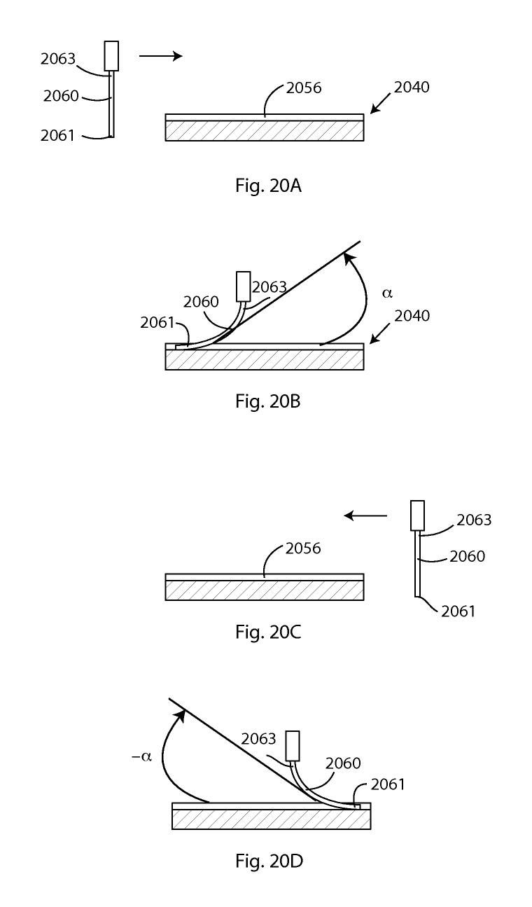

For instance, as shown schematically with reference to FIGS. 20A-20D, if the support end 2063 of the dispensing tube 2060 is maintained substantially perpendicular to the plane of the work piece 2040, vertical, as shown, then the tube may be moved relative to the edge of the work piece (toward the right as shown in FIG. 20A), such that when it contacts the work piece 2040, the support end 2063 remains perpendicular to the work piece, but the dispensing end 2061 is flexed away from perpendicular, assuming a curved shape toward its tip as shown in FIG. 20B. When the dispensing end of the tube traverses the entire length of the work piece path groove 2056, as shown in FIG. 20C, it may move beyond the end of the work piece 2040, and then the direction of relative motion may be reversed (toward the left, as shown). The capillary tube 2060 is moved again toward the work piece, until it contacts the edge (opposite to the edge mentioned first above) and the capillary tube dispensing end 2061 flexes again, assuming the same shaped curve relative to the surface, but with an opposite sign, or direction as shown in FIG. 20D.

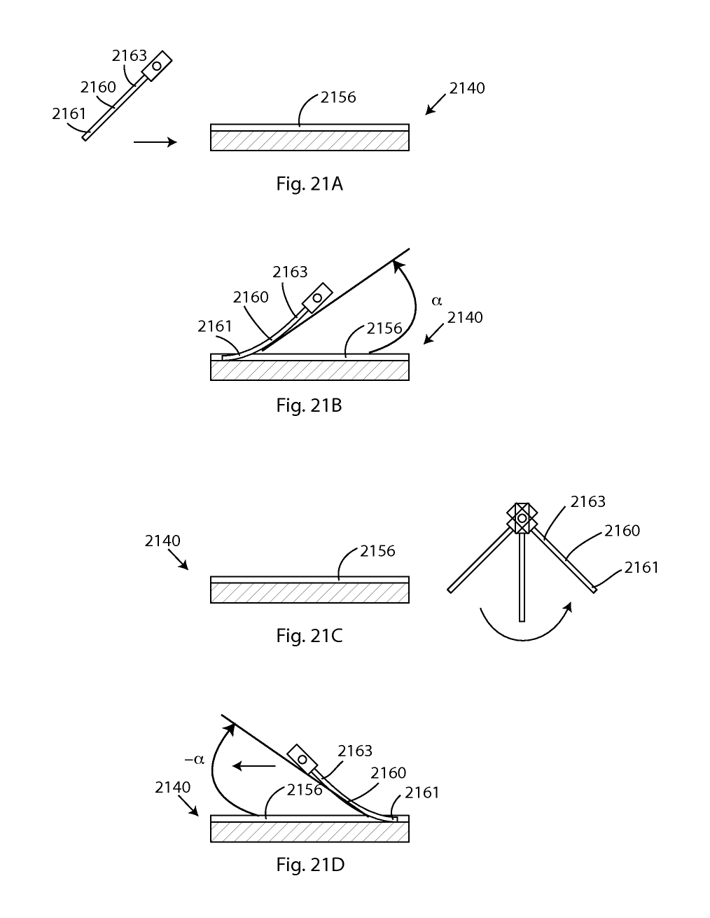

Rather than maintaining the support end of the dispensing tube perpendicular to the surface of the work piece, as shown schematically with reference to FIGS. 21A-21D, it is also possible to incline the support end 2163 of the dispensing capillary tube 2160 at a first angle relative to the surface of the work piece 2140, and then, after relative motion between the tube and the work piece (toward the right as shown in FIG. 21B) results in the tube having traversed the entire length of the surface of the work piece 2140 and beyond, the support end 2163 of the dispensing tube 2160 can be inclined, through perpendicular, to an opposite angle, as shown in FIG. 21C as the direction of relative motion is reversed, and the traversal begins in the other direction as shown in FIG. 21D. Though a simple pivot is shown, another suitable linkage such as a four bar linkage could be employed, such that the dispensing tip is not displaced further below the plane of the work piece during the motion. Whether it is advantageous to incline the support end 2163 of the dispensing tube will depend on the flexibility of the tube, the friction between the tube and its moving environment, the degree of complexity of the relative motion device, etc.

One advantage of the self-alignment and tracking of the dispensing capillary tube to the groove in the texture is that the dispensing capillary tube drive mechanism does not have to be pre-aligned to the groove so that the dispensing tube moves along perfectly aligned with the physical work piece path along which material is to be dispensed, even if the physical unconstrained dispensing end path 1610 is not so perfectly aligned with the physical work piece path 1604. That is, no machine vision or other system is needed in the machine that does the dispensing. Further, small variations in the spacing or straightness of the grooves can be accommodated. In general, tracking and alignment tolerances are relaxed.

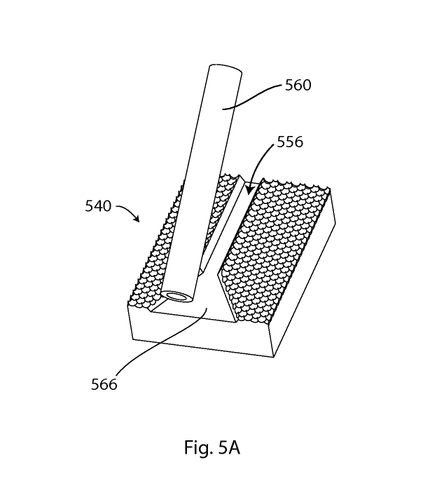

While the dispensing capillary tube will stay in the physical work piece path groove once within it, it must first find the groove. A convenient way to accomplish this is to provide a lead-in feature, as shown schematically with reference to FIG. 5A, FIG. 5B. These features radiate out from the ends of individual grooves 556, and may take the form of raised chevrons or wedge-shaped depressions in the work piece surface. These features align the capillary dispensing tube at the beginning of a pass, but they provide no restoring force once the capillary has traveled into the straight section of the groove. For example, FIG. 5A shows a triangular lead-in feature 566 on a work piece 540. The dispensing capillary tube 560 will ride along one wall of the triangular lead in 566 and be drawn toward the center and then enter the groove 556. Such a lead-in feature is one form of an alignment guide as that term is used herein, of which at least one other will be discussed below. In general, an alignment guide aids in establishing the dispensing capillary tube within the groove, and maintaining it there or restoring it to within the groove if it becomes displaced.

FIG. 5B shows an alternative form of lead-in feature 567 which is composed of two lead-in grooves 567a and 567b, which converge to the groove 556 to be treated. Such a lead-in feature may be advantageous where the texturing process is not well suited to etching extended regions such as 566 in FIG. 5A. The dispensing tube will be caught by either groove 567a or 567b and be pushed sideways so that it tracks into the groove 556. The radiused transitions 567r are arcs tangent to the groove 556 and aid in gently urging a tube following either track 567a or 567b into groove 556, thereby minimizing the chance that the tube will pop out of the groove at the junction of the lead-in tracks and the groove 556. For clarity, no light trapping texture is shown in FIG. 5B.

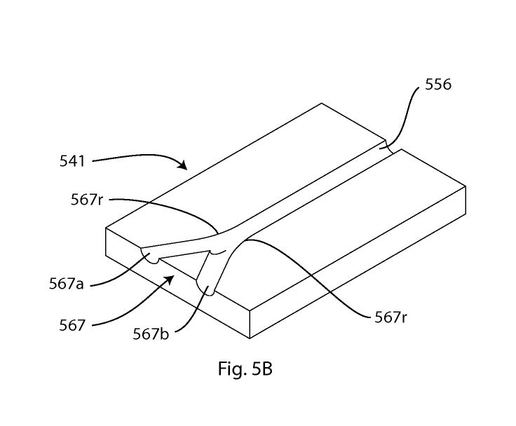

Another means to enhance tracking of the capillary in the groove is to use a dispensing capillary tube that is not round. Several tracking features that derive from a non-circular end of the dispensing capillary tube are discussed below. For example, as shown schematically in FIG. 6, a dispensing capillary 660, with an approximately elliptical cross section, with the major axis arranged vertical, will fit deeper into the groove 656 than would a circular tube of the same cross-sectional area, and would thus improve tracking. One way to make such an approximately elliptical cross section is to provide a crimped or squashed tube. For instance, a tube may be flattened partially, such as by squeezing it between two rollers, which plastically deform the tube. Then, the tube is sliced within the flattened region, thereby establishing two tube portions, each with an end that has an approximately elliptical cross section.

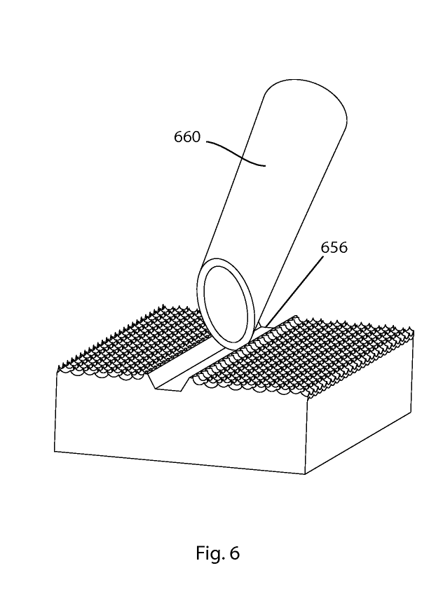

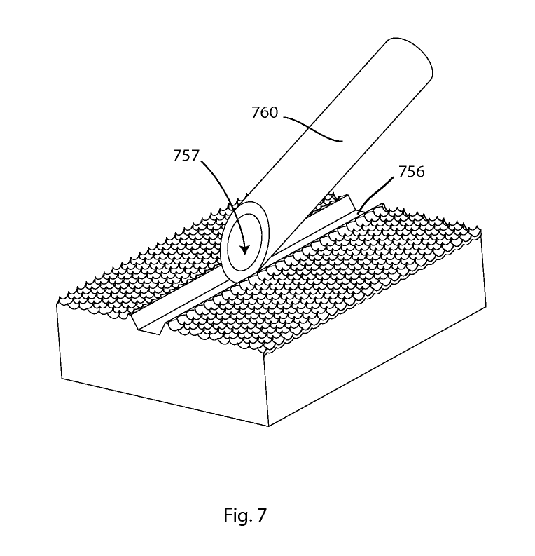

As shown schematically with reference to FIG. 7, it is also possible to provide a dispensing capillary tube 760 with a circular cross-section, but that has the tip 757 cut at a bevel, which also provides for better tracking in the groove. The resulting shape will possess a sharper tip than a square-cut nozzle, and the sharper tip will track more easily in a groove. Further, the tip may be creased down to make a hoe-shaped tip that will track more precisely still.

It is also possible to provide a dispensing capillary tube having a cross section with a protrusion at the bottom of the dispensing capillary tube. The protrusion could be used to enhance tracking by further keeping the dispensing capillary tube from jumping from the groove.

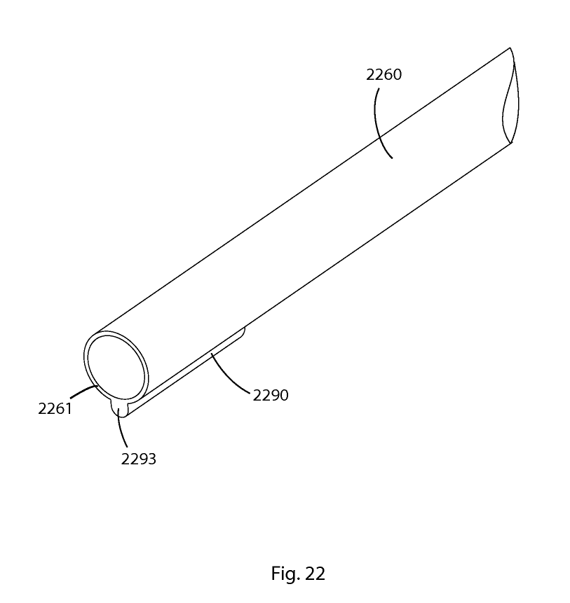

One type of tracking feature, as that term is used herein is in the form of a protrusion and may take advantage and make dual use of a structure discussed above in connection with providing a positive force forcing the dispensing capillary tube into the semiconductor surface. A cast protrusion feature 1890, 1790 is mentioned above and shown in FIGS. 18 and 17 respectively, which can be filled with magnetic particles. Such a cast feature 1790 can also be sized and shaped to mechanically track within the groove 1756, much as the bevel, or creased tips, just discussed above. In fact, if such a cast feature is molded onto the tip of the dispensing tube 1760, 1860, for instance of epoxy, as discussed above, it can be any shape and size suitable to engage the groove 1756 positively. For instance, FIG. 18 shows a generally circular cylindrical body 1890 on the bottom (as shown) of the dispensing tube 1860, with a rounded face 1893. FIG. 22 shows a similarly shaped feature 2290, on the dispensing tube 2260 but with a flat face 2293.

A useful option is to fill this cast feature with wear resistant particles, such as particles of silica or of another ceramic. In this manner, the tracking feature will not wear away with prolonged use.

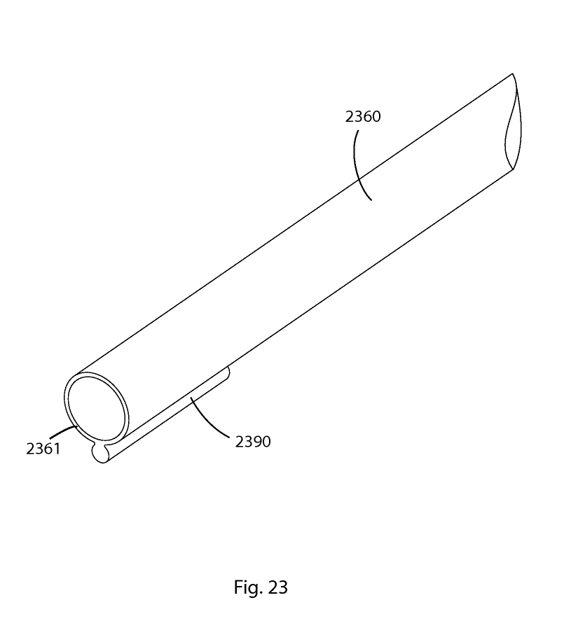

As shown with reference to FIG. 23, a tracking feature can also be made by adhering a small diameter wire 2390 to the end of a dispensing tube 2360. The wire can be metallic, ceramic or polymeric. For example, a 25 micron diameter stainless steel wire can be bonded to the side of a 100 micron outside diameter polyimide tube using an epoxy. The wire acts as a tracking feature, which has excellent resistance to abrasive wear while in contact with the work piece.

Another means of fabricating a capillary tube with a tracking feature is to extrude or draw a plastic tube with the appropriate cross section. Drawing is an especially advantageous method. A rod of the chosen polymer is machined into a scaled up version of the desired cross section. The end of the rod is heated and drawn down to the desired final dimension.

Thus, some reasonable tracking features include, but are not limited to: a molded bump or other shape at the dispensing end of the tube; an out-of-round cross-section dispensing end, such as an elliptical cross-section tube, or tube dispensing end; a bevel-cut dispensing end tip; a hoe-shaped tip and a tube having a protrusion at the bottom of the dispensing end. Rather than a molded bump, the tube may have an integral bump, which has been machined, or provided by crimping the tube end. A circular cross-section tube that is sized and shaped to mechanically track the work piece path, as defined above, is considered itself to constitute a tracking feature as that term is used herein, even without any additional tracking feature, such as external protrusions.

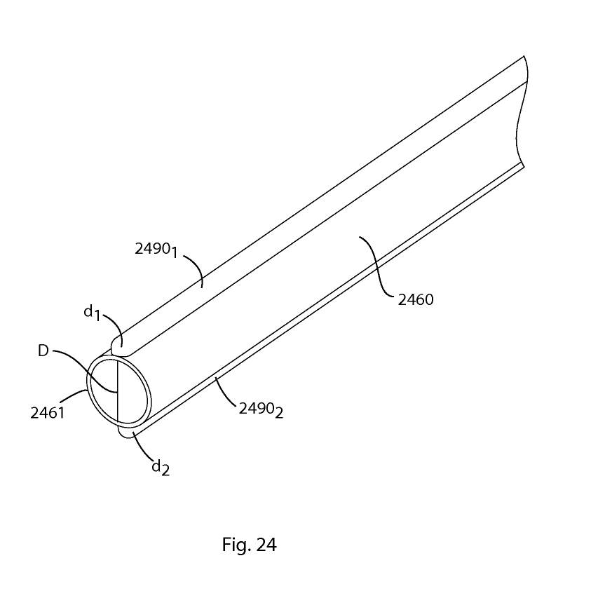

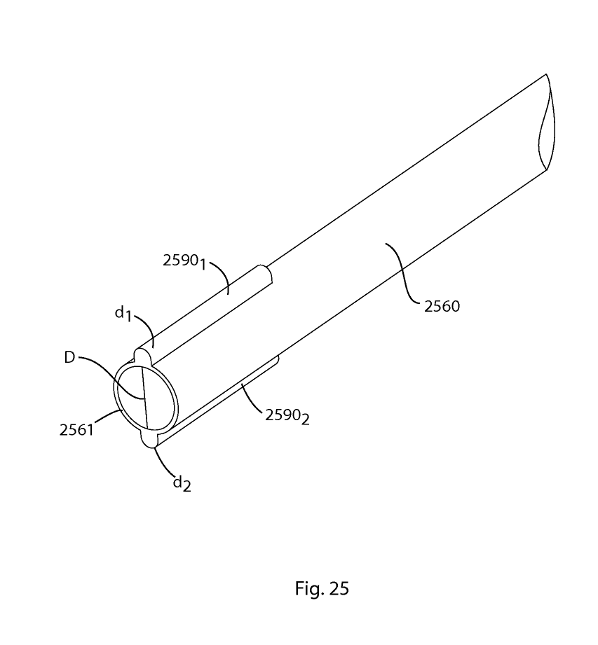

The tracking feature may be present only at the dispensing end of the tube 1861, 2261, 2361, as shown in FIGS. 18, 22 and 23 or as shown in FIG. 25 as at 2590₁, 2590₂ for two flat face features, or as shown in FIG. 24 at 2490₁, 2490₂ for two rounded face features along some or all of the entire length of the tube. The tracking feature should also, preferably, be sized and shaped, in some manner to mechanically track a path defined in the textured work piece surface. Thus, the lateral dimension of the tracking feature is beneficially about equal to or smaller than the lateral dimension of the groove with which it is intended to work. Its purpose is to fit well into the groove and provide high restoring forces for tracking even when the capillary tube itself is significantly larger than the groove.

For reasons related to bidirectional treating, as discussed above in connection with FIGS. 20 and 21, further as shown in FIGS. 24 and 25, it may be beneficial that a tracking feature 2490₁, 2490₂ be present on opposite ends d₁, d₂ of a single diameter D of the capillary dispensing tube 2460. FIG. 24 shows tracking features parallel to the axis of the dispensing capillary tube 2460, along a substantial length of the outside of the tube, with rounded faces. FIG. 25 shows tracking features 2590₁, 2590₂, only near the dispensing end 2561, with flat faces.

The tracking feature helps the dispensing tube to mechanically track within a groove during a pass along the work piece in a first direction, with the flexible tube dispensing end inclined with respect to the work piece at a first angle, α, or a curve with a curvature of a first sign (e.g., concave to the left, as shown in FIG. 20A), and contacting the work piece at a location d₁, at one end of a diameter D. Then, as discussed above, the relative motion mechanism can reverse direction. The flexible tube dispensing end flexes, and then becomes inclined with respect to the work piece at a second angle of −α and/or a second curvature with an opposite sign (e.g., concave to the right, as shown in FIG. 20D) from the first sign. Also, the point of contact will then be d₂, at the opposite end of the diameter d of the dispensing tube from d₁. The relative motion device then draws the dispensing tube along in a direction opposite to that first traversed, such that the point of contact d₂ remains in contact with the surface for the entire next pass. At the end of the second pass, the relative motion device reverses direction again, and the point d₁ again becomes the point of contact.

It may in some cases be beneficial to provide tracking features in one, two or more, for instance four locations around the circumference of the cross-section of the end of the dispensing tube. In some cases the dispensing end of the tube may have a non-circular cross-section. In such a case, it may not be proper to refer to the extent of the cross-section of such a shape as a diameter. As used herein, cross-extent or cross-sectional extent shall mean the distance across such a cross-sectional area.

In the case where the tracking feature runs along the length of the dispensing tube, such as shown at 2490₁, 2490₂ in FIG. 24, both the single and double tracking features have the advantage that the stiffness of the dispensing tube in the plane of the tube that is perpendicular to the work piece is higher than the stiffness of the tube in displacement parallel to the work piece. In this way, the maximum allowable misalignment of the dispensing end 2461 of the tube, from the groove, will be larger than it would be in the case of a circular tube, for a given amount of preload displacement.

In general it may be of interest to provide a dispensing tube with different stiffness for different axes, particularly for the stiffness in the plane of the work piece to be different than the stiffness normal to the work piece. Although adding external tracking features will have this effect, it may be desirable whether or not a tracking feature is incorporated. It may be desirable to provide different stiffness without modifying the shape at the tip. For instance, the capillary dispensing tube may be co-extruded or otherwise fabricated with different material properties at different sectors of the circumference. Alternatively, there may be a thicker wall portion along one such line, but not others, or there may be a strip of tape or some other material adhered along one such line, but not along a line at an opposite side of the central axis. A stiffening element such as a fiber may also be molded into the walls of the capillary tube at the top and bottom of the tube in order to increase the vertical stiffness of the tube. A bead of polymer or glue may be provided along one or more lines, etc.

When there is a tracking feature and/or when the tube is made to be stiffer vertically than it is horizontally, the maximum restoring force is still proportional to any preload force. However, unlike the simpler case discussed above, the maximum restoring force will be larger and even significantly larger than the preload force.

The wetting angle between liquid and the surface of the groove must be controlled to be within an allowable range. If the liquid is too wetting, it may climb over the edge of the groove and wet in areas outside the desired regions. If the liquid is too non-wetting, the liquid will break up into beads after it is dispensed into the groove. There is, however, a wide range of wetting angles that will result in successful operation. The rheology of the fluid will also play a role in the process. It may be desirable to have a fluid which is shear thinning so that the fluid may be pushed through the dispensing capillary tube, but once it is in the groove, the viscosity will increase and the fluid will stay where it is dispensed. It may also be desirable to have a fluid with a yield stress—a stress below which it does not move at all. This will further guarantee that the fluid stays within the groove. However, some flow within the groove may be desirable so that the liquid flows out to fill the groove including touching the sidewalls of the groove. The motion of the fluid in the groove can also be arrested by evaporation of the liquid vehicle. The wafer may be held at elevated temperature during the dispensing operation in order to further promote this evaporation. Another mechanism of restricting the motion of the fluid once it is in the groove is to cause the liquid to freeze, flocculate, gel or cross-link after it is dispensed into the groove.

Flocculation, gellation and cross-linking can be due to a chemical agent mixed in the material to be dispensed a short time prior to dispensing. Alternatively, the chemical agent that causes flocculation, gelling or cross-linking, can be in the ambient surrounding the work piece. For example, if the work piece is maintained under a blanket of carbon dioxide, a water based material that is dispensed will rapidly drop in pH—an effect that can be used to effect flocculation, gellation or cross-linking. A dilatant or shear-thickening fluid may be advantageous because the fluid column dispensed by the tube would be less likely to pinch off and form droplets. This is particularly important where the deposited cross-section is less than the cross-section of the inner diameter of the dispensing tube.

The nature of the light trapping texture near the grooves can also help define and retain the clear definition of the edges of the metallized regions. If the work piece outside this groove edge is flat, confinement is possible. However, confinement becomes more robust if the edge of the groove is raised, or if the work piece outside the groove is lowered.

It has been found that if, as shown in FIG. 3A, the edge 361 of the groove 356 that tops the walls 359 is sharp, and has relatively steep inclines on both sides, then the deposited material stays within the groove, and does not wet the adjacent upper surface of the work piece. This can be achieved such as is shown in FIG. 3A, with a steep incline at the wall 359 on one side of the edge 361, and the steep walls formed by the light trapping texture pits 343, which form the textured surface 342. It has been found that in some cases, if the pits are spaced closely adjacent the edge atop the wall 359, there is no wetting. While, in other cases, if the pits are spaced further away, leaving a more substantial scallop edged, flat surface between the wall 359 and the removed pits, the upper surface may be undesirably wetted. This is also illustrated with a somewhat different context in FIG. 15, which shows a capillary dispensing tube 1560 moving along a groove 1556, dispensing material 1564 that contains liquid, which necks down, fills the groove, but does not overflow beyond the edge 1571 of the groove, into the hexagonal array 1542 of pits 1543. In FIG. 15 as shown, the groove 1556f is shown filled with material, while the groove 1556e remains empty.

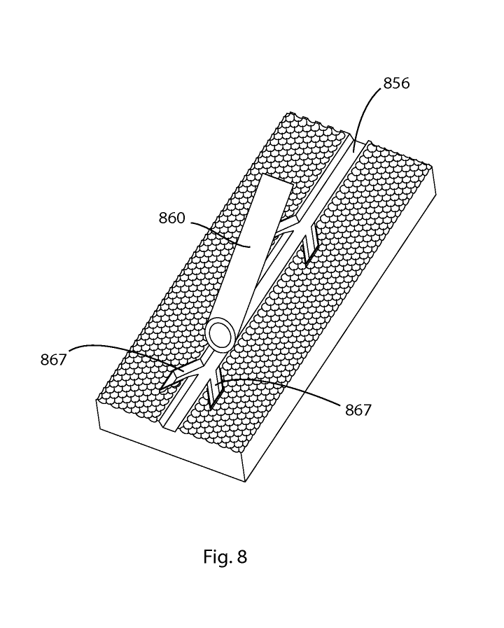

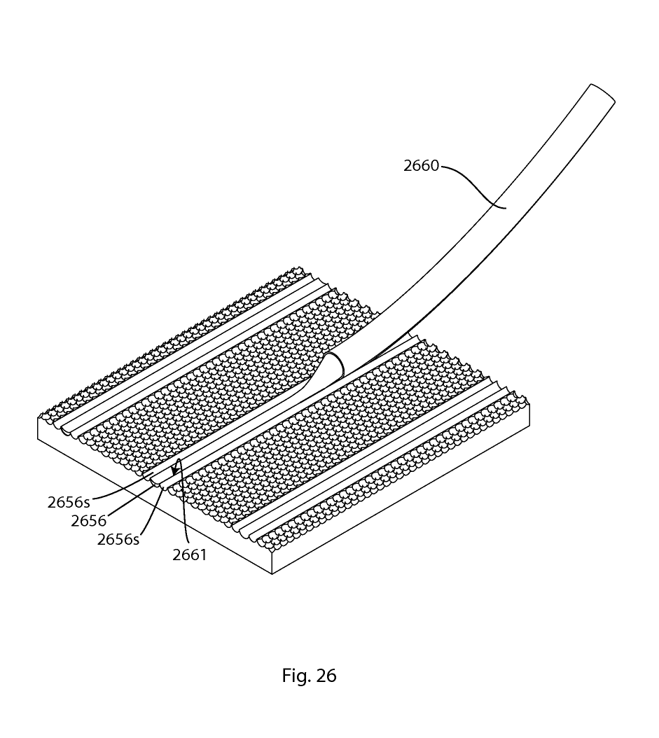

Another geometry that has been found to prevent undesirable wetting of the upper surface, is shown schematically in FIG. 26. An additional groove 2656s is provided adjacent each side of the main groove 2656. Because the walls of the adjacent grooves 2665s fall away steeply from the intervening edge 2661, there is a steeply inclined surface on each side of the edge, and the deposited material 2664 does not wet beyond the edge. Such a structure is also shown schematically in FIGS. 8A-8D and 14 of PCT application Serial No.: PCT/US2009/02422, entitled METHODS TO PATTERN DIFFUSION LAYERS IN SOLAR CELLS AND SOLAR CELLS MADE BY SUCH METHODS Filed: Apr. 17, 2009, inventors Andrew M. Gabor and Richard L. Wallace, the disclosure of which is fully incorporated herein by reference.

The wetting of the fluid to the material of the dispensing capillary tube may also be controlled to reduce the tendency of the fluid to wet up the outside of the dispensing capillary tube

The flow rate through the dispensing capillary tube should preferably be controlled. The approximate flow rate needed can be estimated by calculating the cross sectional area of the groove that is to be filled and multiplying by the traverse speed of the dispensing capillary tube. For example, if a semi-cylindrical groove of 30 micron width is to be filled with liquid, the cross sectional area is 3.5×10⁻⁶ cm². If this dispensing capillary tube traverses at 10 cm/s, the required flow rate is 0.002 cc/min. The flow may be regulated by the application of pressure to the liquid with the flow controlled by the viscous pressure drop of the liquid in the dispensing capillary tube. For instance, there may be a pressurized volume of material that is hydraulically coupled to the support end of the capillary dispensing tube. Other metering methods may be used, such as a metering pump.

The speed with which the treatment can be accomplished is important to the economics of the process. The velocity of the dispensing capillary tube over the groove may be quite high, certainly as high as two m/s and perhaps as high as ten m/s. There are several factors that might limit this velocity. For instance, if the material to be dispensed has a high viscosity, its rate of dispensing may be limited.

The ability to move the work piece and/or dispensing capillary tube with satisfactory trajectory control is important. (As discussed above, the physical unconstrained dispensing end path 1610 can be misaligned a bit from the physical work piece path 1604, because the mechanical and capillary force tracking in the groove will compensate for some degree of error ε.

Another form of alignment guide may be provided that will help if a dispensing tube has become dislodged from the groove. This form of alignment guide is referred to generally herein as a restoring feature, or a steering feature.

As shown in FIG. 8, a textured border adjacent the design groove 856 for dispensing can be provided. These are alignment guides of diagonal grooves 867, similar to the triangular lead-in feature 566 illustrated above with reference to FIG. 5A, which will steer or restore a displaced traveling dispensing capillary tube 860 back into the intended groove 856 path (also referred to as the physical work piece path 1604 in FIG. 16). They are specifically also referred to herein as restoring features. The movement of the dispensing capillary tube 860 tip over the oriented texture 867 surrounding the design groove 856 creates an oblique force on the tip, (being a combination of frictional and normal force due to the topography) tending to drive it towards the intended path. This restoring force is generated by the movement of the tip across diagonally-posed restoring feature elements in the surface texture. The steering features are mirrored on either side of the dispensing groove 856.

Many textures that create an oblique frictional force to a moving dispensing tube tip provide a possible steering, restoring feature. Linear grooves are only a small class of these features.

Thus, both lead-in features and restoring (steering) features of the surface of the textured semiconductor body are referred to herein generically as alignment guides.

Lead-in features such as those described above, may obviate the need to have a separately defined groove 856 along the intended physical work piece path 1604 for dispensing. The intended physical work piece path 1604 would then be defined by the line of convergence between two oppositely-posed sets of textured material that straddle the physical work piece path 1604 for dispensing.

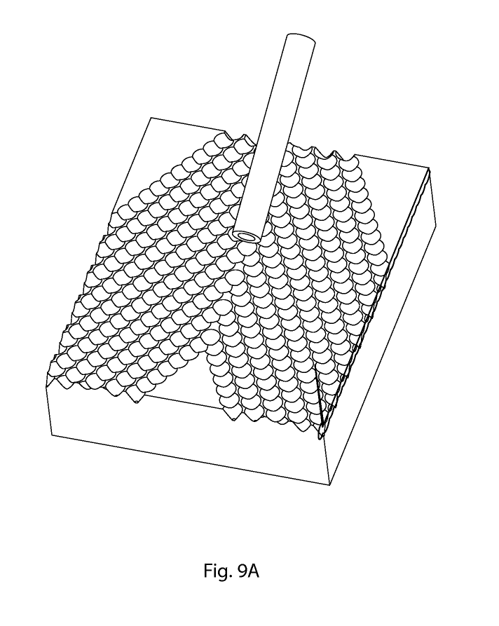

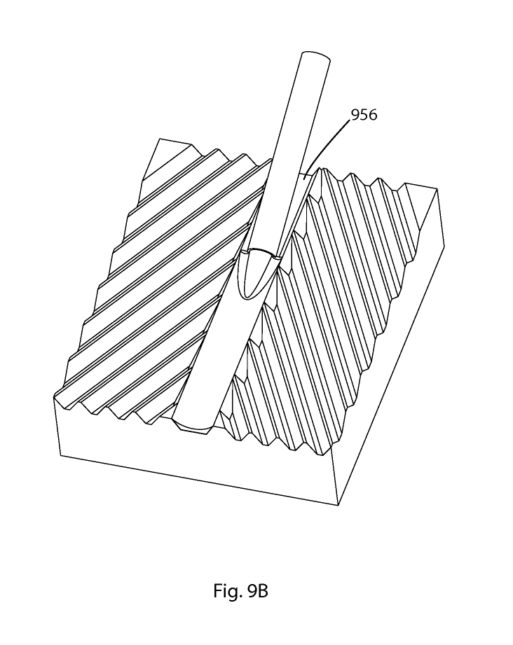

FIG. 9A shows a pattern that is similar to the pattern from FIG. 8, but there is no physical work piece path 1604 groove. There are patterns of pockets that are mirror images of each other adjacent the line. For the design shown in FIG. 9A, if the dispensing capillary tube moves generally from lower left to upper right, the physical work piece path would be at the convergence of the oppositely angled rows of hemispherical pockets, as shown where the capillary tube rests. Alternative designs not shown are similar to that shown in FIG. 9A. The patterns may be transverse ridges.

The design shown in FIG. 9B, is similar to that discussed above in connection with FIG. 9A, except that there are patterns of transverse ridges, which converge upon a groove 956, provided at the physical work piece path 1604. Fluid is shown being dispensed into the groove.

The purely diagonal features discussed above are not the only features that will steer a traveling dispensing capillary tube tip obliquely. Others include pits spaced at a different spacing, ziz-zag patterns of ridges and grooves that lead by skips and hops.

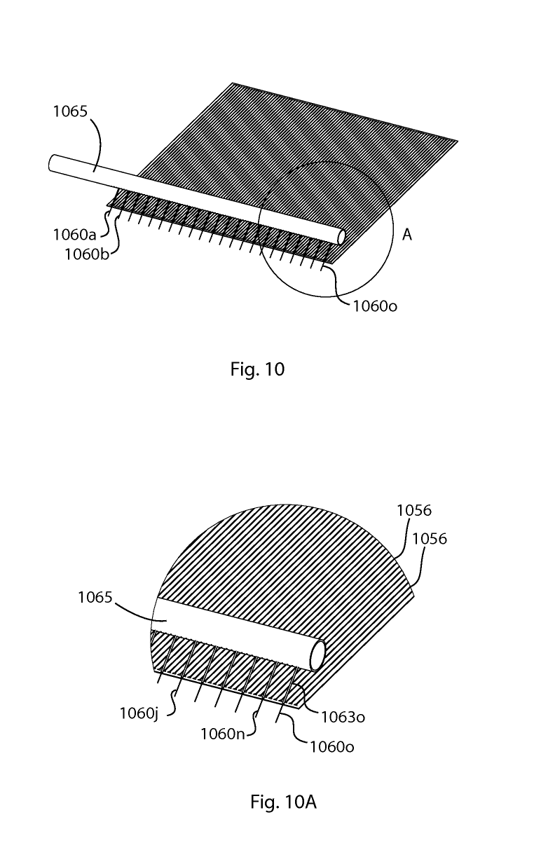

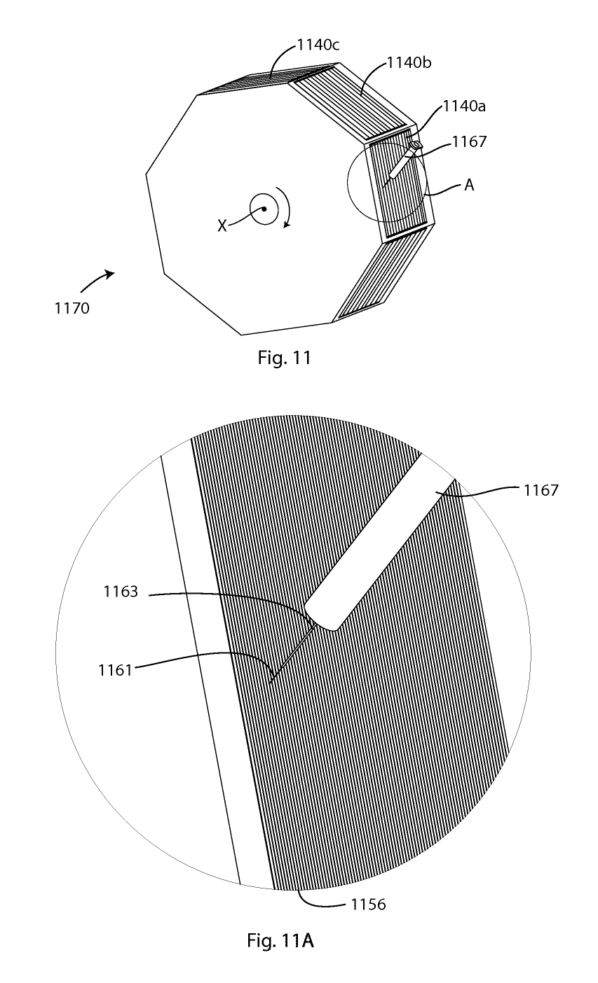

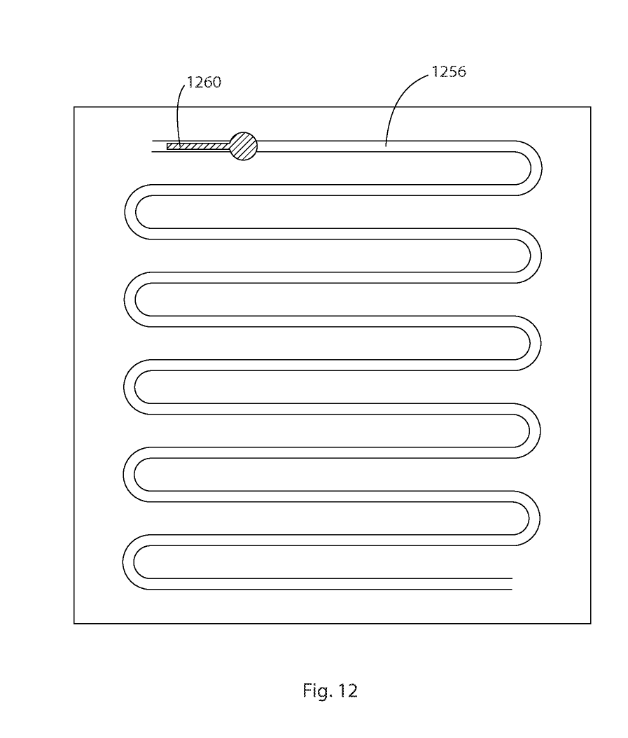

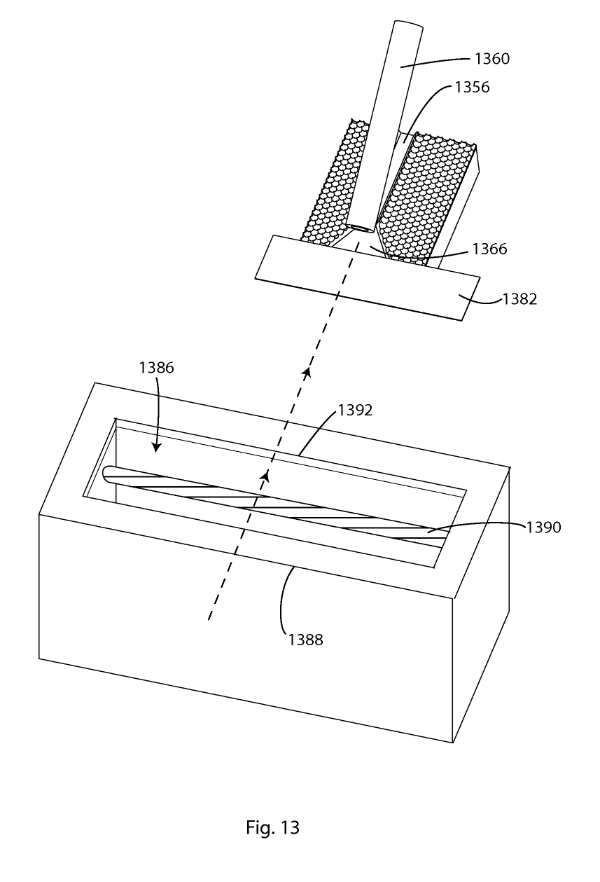

The textured surface of the wafer, including the alignment guides, such as lead in features, similar to that shown in FIG. 13, and the restoring features, such as shown in FIGS. 8, 9A and 9B, can be established by any suitable means. A particularly attractive general family of techniques useful for some, but not all of these features, is described in PCT application PCT/US2009/02423, entitled WEDGE IMPRINT PATTERNING OF IRREGULAR SURFACE, Inventors: Benjamin F. Polito, Holly G. Gates and Emanuel M. Sachs, filed on Apr. 17, 2009 published on Oct. 22, 2009, under No. WO 2009/128946, the full disclosure of which is hereby incorporated herein by reference. An additional attractive technique for making these features is by laser scribing.

The PCT/US2009/02423 case discloses patterned work pieces for photovoltaic and other uses that are made by pressing a flexible stamp upon a thin layer of resist material, which covers a work piece, such as a wafer. The resist changes phase or becomes flowable, flowing away from locations of impression, revealing the work piece, which is subjected to some shaping process, typically etching. Portions exposed by the stamp are removed, and portions that protected by the resist, remain. A typical work piece is silicon, and a typical resist is a wax. Work piece textures described therein include extended grooves, discrete, spaced apart pits, and combinations and intermediates thereof. Additional textures such as some of those described herein with respect to lead in features and restoring force features may be similarly provided. Platen or rotary patterning apparatus may be used. Rough and irregular work pieces may be accommodated by extended stamp elements. Resist may be applied first to the work piece, the stamp, or substantially simultaneously, in discrete locations, or over the entire surface of either. The resist de-wets the work piece completely where desired.

As shown in FIGS. 10 and 10A, to attain a high rate, a multiplicity of dispensing capillary tubes 1060a-1060o may be used, each dispensing in a separate groove 1056 for an individual finger 1060a-1060o. For example, if a wafer has one hundred fingers 1056, one hundred dispensing capillary tubes 1060 could be used so that material is dispensed to one hundred fingers of the wafer in one pass. The one hundred dispensing capillary tubes may be disposed in a single row. Or, (as shown schematically for a smaller number of tubes Y (twenty-two as shown) in FIG. 10, Y dispensing capillary tubes 1060a could be used so that material is dispensed to 10×Y fingers of the wafer in ten passes, with the dispensing capillary tubes incremented laterally between passes.

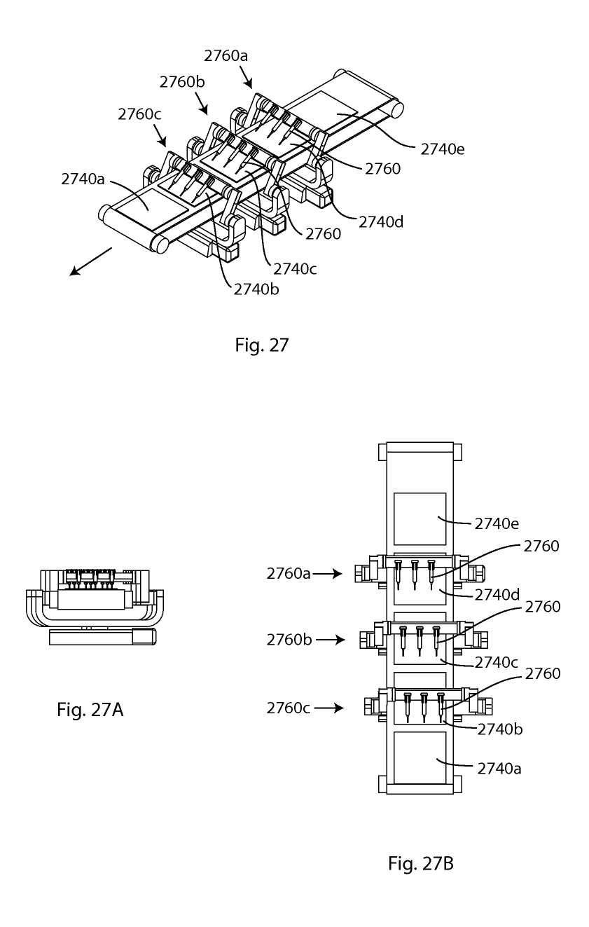

Or, as shown schematically with reference to FIGS. 27, 27A (end view) and 27B (plan view), ranks of dispensing capillary tubes 2760 could be arranged in a line, with each rank displaced laterally from each other rank (as seen from FIG. 27A), so that after a work piece 2740 has passed by all of the ranks 2760a-2760c of the entire assembly, every groove has been treated. They may be separated into groups of, for instance ten, twenty or twenty-five, spaced apart along the direction of relative motion of the dispensing apparatus and the work pieces For clarity of the figures, only three ranks 2760a, 2760b and 2760c of three dispensing tubes each are shown. However, it is possible that there be many ranks, each with many dispensing tubes, as discussed above.

FIG. 10A shows the polymeric dispensing capillary tube 1060, extending from a steel tube 1063. The steel tubes 1063 are fixed in a support assembly 1065, which is itself coupled to a relative motion drive mechanism, not shown.

Whether with a single dispensing capillary tube, or a multiplicity of dispensing capillary tubes, the rate can be increased by treating a number of wafers in a line. This has the advantage (for cases where the dispensing tube is reciprocated over the work piece) that the time spent accelerating and decelerating the dispensing capillary tube at the beginning and end of travel for each reciprocation, is reduced to a smaller fraction of the total process time.

A challenge in a multiple capillary dispensing tube device such as that shown in FIG. 10A is to keep the flow rates the same from dispensing tube to dispensing tube despite small variations in tube diameter or length and also the possibility of deposits accumulating in the tubes. A particularly attractive method is to independently control the temperature of each capillary tube and thereby change the rheology of the liquid and the flow rate. This is particularly effective for paste like materials where the viscosity typically decreases sharply with increases in temperature. Thus, if the flow from a particular tube is found to be low, the temperature of the tube can be increased. The temperature can be changed by the action of a small heater surrounding the tube or by shining light on the tube. A conductive coating deposited on the tube can be coupled to by a radio frequency coil to provide heating. Alternatively a thin conductive film on the tube can be used as a resistive heater. Such conductive films can be deposited directly on polymeric and glass tube materials. An insulating layer must be provided on metal tubes. The flow rate may be determined in situ by thermal means as well, for instance by measuring the time of flight between a localized heat source at one region of the dispensing tube and a subsequent temperature measuring device downstream of the tube, or by measuring the temperature rise in the fluid resulting from a known thermal power input. The measurement and control may be effected by the same apparatus.

Alternatively, as shown schematically with reference to FIG. 11 and FIG. 11A, a plurality of work pieces, such as wafers 1140a-1140c may be disposed on the faces of a drum 1170 with flats and, with the drum rotating continuously in one direction as indicated by the arrow. The dispensing capillary tube 1160 (FIG. 11A) could then be traversed in a direction parallel to the axis X of the drum (about which the drum rotates) while being moved in and out (toward and away from the wafer) to provide the rise and fall needed as an individual wafer is traversed. The steel tube 1163 supports the dispensing capillary tube 1160, and is coupled to a larger volume body 1167, such as a syringe barrel, shown schematically at FIG. 11.

High rate could also be achieved by creating the metallization finger groove 1256 in a serpentine pattern as shown in FIG. 12 and having a single dispensing capillary tube 1260 dispense material to the entire serpentine groove at substantially constant velocity (no lead in feature is shown in this Figure).

There is an advantage to preventing reactant liquids from coming in contact with the edge of the wafer (primarily to avoid electrical shunt paths). As describe thus far, the implementation of the dispensing process, drags the dispensing tip across the edge of the wafer, exposing the edges to the reactant fluid. Alternatively, as shown schematically in FIG. 13, the edges can be masked with a thin layer of masking material 1382 (e.g. paper tape) to prevent the liquid from touching the edge of the wafer. It is not necessary that this layer be bonded to the wafer surface, though it may be. Alignment to the edge is not critical, though the mask can not entirely cover the lead-in features 1366 of the grooves 1356 for the fingers, or they will lose their effectiveness. The masking material may be disposable or cleaned and re-used. The same concept of masking may be employed at the end of a groove, again to prevent dispensing on the very edge of the cell. The paper tape masking materials running along the length of the cell can simultaneously mask a multiplicity of capillary tubes. Alternatively, in the serpentine path embodiment, there is only one entry and one exit to be masked.

The tip of the dispensing capillary tube may accumulate material on its outer surface near the tip. This can happen due to the fluid material wetting back onto the outer surface of the dispensing capillary tube. It can also be a result of the capillary action between the tube and the edge of the groove in which it is tracking during dispensing. It is advantageous to periodically clean the outer surface of the dispensing tube to keep the edges of the dispensed material well defined. Such cleaning may be accomplished by several means, either alone, or in combination. One way is to have the tip traverse a strip or pad of material. For example the masking material 1382 described above in connection with FIG. 13, may also serve the function of cleaning the tip. The masking material 1382 can be made of an absorbent material with a little bit of surface roughness to help remove any material from the outside of the capillary. The material that is removed would then be absorbed by the masking material. Paper or a nonwoven polymer fabric with sufficient absorbency would work, for example. This approach has the advantage that the tip is cleaned before each pass of the dispensing tube over the work piece. Alternatively, the cleaning strip or pad may be an additional piece of material and not integrated into the masking strip.

The tip may also be cleaned by periodic immersion in a cleaning bath 1386, for instance which may be ultrasonic, arranged adjacent the work piece. The capillary dispensing tube 1360 can be traversed along the path indicated by the dotted line and arrows. It may be dipped explicitly into the liquid bath 1386, for instance by vertical motion of the relative motion device 241 (FIG. 2) Or, the designer may take advantage of the flexibility of the dispensing tube 1360, and may arrange the travel path such that when the capillary dispensing tube is at the liquid reservoir, the tip is submerged in the liquid 1386. As the capillary dispensing tube approaches the outer edge 1388 of the reservoir, the tube deflects, and then when it reaches the liquid 1386, it snaps into the liquid and is cleaned by action of the ultrasonic generator 1390. The tube continues forward along the dotted line, and encounters the inner edge 1392 of the reservoir, flexes, and eventually emerges from the liquid and is drawn along toward the work piece. Such ultrasonic cleaning station may be located along one or both edges of the work piece. The immersion time may be short, even less than one second such that the motion is not interrupted.

FIG. 14 shows, schematically, a work piece, such as a wafer 1440 having a groove 1446 for a metallization finger that varies in cross-section. The amount of fluid dispensed per unit length of groove can be varied with precise control by changing either the speed of the dispensing tip relative to the wafer, or by modulating the dispensing pressure. A means to vary metallization finger cross-section is desirable, because the current carried by the metallization finger is higher closer to the bus wire 1444 (current collection point 1445). To optimize the tradeoff between reduced resistive power losses and cell area shading, due to a wider metallization finger 1446, a metallization finger geometry that has greater cross-section nearer to the bus wire offers advantages. An ideal shape would be parabolic, as viewed from above, because the power loss is proportional to the square of the current, which increases linearly toward the bus wire.

The increased flow rate of dispensed fluid may be accommodated by an increased width of finger to ensure retention of the fluid in the groove by capillarity.

Methods have been described herein in the context of fabricating solar cells on discrete wafers as work pieces. The methods may also be applied to larger format work pieces and even to continuous roll applications. The methods may also be applied to electronic applications other than the manufacture of solar cells.

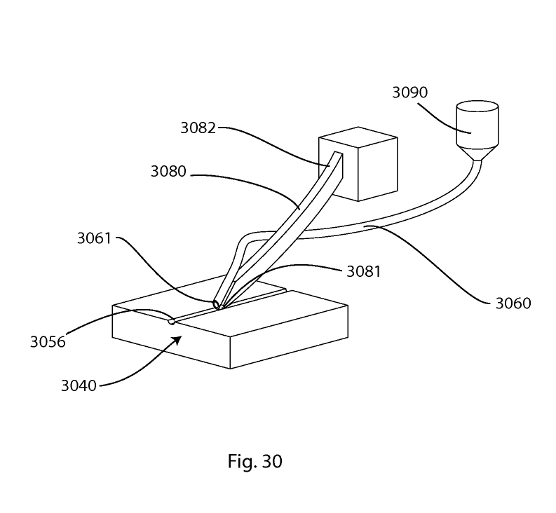

While in the previously described embodiments the flexible element that provides physical positioning of the dispensing tip with the necessary compliance for tracking and the fluid-carrying conduit are one and the same, this is not a necessary characteristic of inventions disclosed herein. In some cases it may be advantageous to provide the compliant positioning with a wire or other purely mechanical element, to which a separate fluid-carrying conduit is affixed at the dispensing end. For example, some dispensed materials may not be chemically compatible with tubing that has the necessary degree of compliance and wear properties. For instance, an aggressive material might be dispensed through a soft, inert tube, for instance of PTFE, and the dispensing tube might be coupled at the dispensing end to a more suitable compliant positioning feature, such as a solid rod composed of metal, quartz, or carbon fiber. Referring to FIG. 30, a flexible positioning element 3080 having a tracking end 3081 and support end 3082 is coupled at the tracking end to the dispensing end 3061 of a fluid-dispensing conduit 3060, such that the tracking end 3081 tracks a groove 3056 in work piece 3040, and the dispensing end 3061 dispenses fluid into the groove 3056. The source end of conduit 3060 is hydraulically coupled to a fluid reservoir 3090.

In many cases, the dispensing tube will be small in diameter and used to address small features as herein described. For this reason, the term capillary tube has been used extensively in this disclosure. It will be appreciated, however, that the scale of implementation of this invention can vary and that larger features might be addressed by larger tubes which might be called simply tubes and not capillary tubes.

This disclosure describes and discloses more than one invention. The inventions are set forth in the claims of this and related documents, not only as filed, but also as developed during prosecution of any patent application based on this disclosure. The inventors intend to claim all of the various inventions to the limits permitted by the prior art, as it is subsequently determined to be. No feature described herein is essential to each invention disclosed herein. Thus, the inventors intend that no features described herein, but not claimed in any particular claim of any patent based on this disclosure, should be incorporated into any such claim.

For instance, the invention of using multiple flexible tubes, with control over the temperature of each independently, or in small groups, may be used independent of any other invention, in particular of any type of tracking feature or alignment guide. A serpentine groove may be used in the work piece, without lead in or restoring features.

Some assemblies of hardware, or groups of steps, are referred to herein as an invention. However, this is not an admission that any such assemblies or groups are necessarily patentably distinct inventions, particularly as contemplated by laws and regulations regarding the number of inventions that will be examined in one patent application, or unity of invention. It is intended to be a short way of saying an embodiment of an invention.

An abstract is submitted herewith. It is emphasized that this abstract is being provided to comply with the rule requiring an abstract that will allow examiners and other searchers to quickly ascertain the subject matter of the technical disclosure. It is submitted with the understanding that it will not be used to interpret or limit the scope or meaning of the claims, as promised by the Patent Office's rule.

The foregoing discussion should be understood as illustrative and should not be considered to be limiting in any sense. While the inventions have been particularly shown and described with references to preferred embodiments thereof, it will be understood by those skilled in the art that various changes in form and details may be made therein without departing from the spirit and scope of the inventions as defined by the claims.

The corresponding structures, materials, acts and equivalents of all means or step plus function elements in the claims below are intended to include any structure, material, or acts for performing the functions in combination with other claimed elements as specifically claimed.

### SUMMARY

Many inventions are disclosed herein, including apparatus of different levels of combination, and methods.

A basic embodiment of an invention hereof is an apparatus for dispensing a material that contains liquid to a textured surface of a semiconductor work piece, the apparatus, comprising a flexible tube having a support end and a dispensing end, the dispensing end comprising a mechanical tracking feature.

A related embodiment may further comprise a body that is less flexible than the flexible tube, the support end of the flexible tube being secured to and hydraulically coupled to the less flexible body.

With an important embodiment, the tracking feature comprises a protrusion at least one end of a cross-sectional extent of the tube. The protrusion may comprise a wear resistant and/or a magnetically attractive material.

The protrusion may comprise a body adhered to the flexible tube. The protrusion may be a body integral with the flexible tube, formed at least in part from the same material as is formed the flexible tube.

The flexible tube has a long axis and a lateral extent substantially perpendicular to the lateral extent. The tracking feature typically has a lateral extent that is less than a lateral extent of the tube.

With a useful embodiment, the tracking feature may comprise two tracking features, each one being a protrusion at opposite ends of at least one cross-sectional extent, or four protrusions, one each at opposite ends of two orthogonal cross-sectional extents. The tracking feature may comprise an extended rib substantially parallel to an axis of the flexible tube along the outside of the tube, along one, two or four lines along the outside of the tube.

Other, related embodiments may have the dispensing end having a cross section that has a first cross-sectional extent that is larger than a cross-sectional extent that is perpendicular to the first cross-sectional extent. The larger cross-sectional extent may be beneficially arranged substantially perpendicular to a plane of a work piece. With this embodiment, the flexible tube dispensing end has a cross-sectional shape that has a protrusion at one end of the first cross-sectional extent

With many of these embodiments, the dispensing end may have a shape selected from the group consisting of: a bevel; a main portion with a protruding portion; a circle; an ellipse, a partially flattened circle.

Typically, the flexibility of the flexible tube is chosen to permit the dispensing end of the tube to mechanically track a physical work piece path despite an error between a physical unconstrained dispensing end path followed by the dispensing end and the physical work piece path.

The flexible tube may comprise a material selected from the group consisting of: a polymer, polyimide, glass, quartz, metal and stainless steel. The flexible tube may be a coated tube.

There would typically be a plurality of additional flexible tubes each of which is secured to the tube support. If so, there may be, thermally coupled to each of the plurality of tubes, a temperature control, each of which may be independently controllable. For instance, each temperature control may be a light positioned to shine upon a respective tube. Each tube may comprise a conductive coating. Each temperature control may be a radio frequency coil.

Typically, the flexible tube dispensing end has a cross section that has an extent arranged along a first dimension that has a component that is substantially parallel to the direction of relative motion between the tube and a work piece, which extent is larger than a second extent of the dispensing end that is perpendicular to the first dimension.

In general, the flexibility of the flexible tube being such as to permit the dispensing end of the tube to follow any deviations in a physical work piece path from a flat plane path.

A related important embodiment of an invention hereof is an apparatus for dispensing a material that contains a liquid to a textured surface of a semiconductor work piece. The apparatus comprises: a work piece support, configured to support a work piece; a relative motion device; and a flexible dispensing tube (generally as described above) having a support end and a dispensing end, the dispensing end comprising a tracking feature, the support end coupled to the relative motion device through a tube support. The relative motion device is configured to cause relative motion of the dispensing end of the tube as compared to the work piece support, along a physical dispensing end path, the flexibility of the tube being chosen such that upon such relative motion, the dispensing end of the tube mechanically tracks a physical work piece path of a textured surface of a work piece supported by the support. The tracking feature may be sized and shaped to mechanically track a physical work piece path defined by a textured surface of a work piece. The tube may have a non-circular cross-section at its dispensing end.

The tube may also have any of the additional features mentioned just in connection with the preceding important embodiments.

There may also be, supporting the work piece, a body that is attracted to the magnetically attractive material. The protrusion may comprise a magnetic material holding a permanent magnetic moment.

The physical work piece path has a characteristic minimum width, the tracking feature having a characteristic width that is less than the physical work piece path characteristic minimum width. The tube may usefully have a diameter of less than about ten times the physical work piece path characteristic width.

A material delivery apparatus may be coupled to the flexible tube, configured to deliver material that contains liquid to the flexible tube. The material delivery apparatus may comprise a metering pump. Or, the material delivery apparatus may comprise a pressurized volume of such material hydraulically coupled to the support end of the dispensing tube.

The work piece support may comprise a fixture that maintains at least two work pieces fixed relative to each other so that a physical work piece path of each are substantially collinear. The fixture may comprise a drum, with work piece locating stations around its periphery.

There may also be, beneficially, adjacent the work piece support, a bath of cleaning fluid.

A very important embodiment of inventions disclosed herein is a patterned work piece upon which a material that contains a liquid is to be deposited, the work piece comprising: a semiconductor body having a first surface; a perimeter edge bounding the first surface; and upon the first surface, a physical work piece path comprising at least one groove having a relatively longer dimension than a perpendicular dimension, the work piece further comprising at least one alignment guide.

With this embodiment, the material that contains liquid is to be deposited by a dispensing tube, having a dispensing end. The at least one groove has a size and shape selected to mechanically track the dispensing end, and to apply a restoring force to the dispensing tube in opposition to any force that tends to disengage the dispensing end from the groove in a direction perpendicular to the long dimension of the groove. The at least one groove may comprise a plurality of substantially parallel grooves. Or, the at least one groove may comprise a serpentine groove, that reverses direction at least one time. There may be, at least one end of the serpentine groove, a mask.

In the case where each at least one groove has two ends, there may be, at each such end, a mask.

In general, the at least one alignment guide may comprise a lead in feature at least one end of the groove and, here, as above, the at least one groove may comprise a plurality of parallel grooves. The lead in features may comprise features selected from the group consisting of: an open triangular space, a chevron, a wedge, a pair of arcs tangent to the physical work piece path and a pair of angled grooves.

In addition, (or alternatively) with a very useful embodiment of an invention hereof the at least one alignment guide comprises a restoring feature adjacent the physical work piece path, including a plurality of restoring features adjacent and along the physical work piece path. The restoring features can comprise features selected from the group consisting of grooves that are diagonal with the work piece path and pits arranged along a line that is diagonal with the work piece path.

For another, related embodiment, an invention is a work piece for which at least one of the grooves has two ends, and has a width at each end that is less than a width at a location between the two ends

With another embodiment, at least one groove follows a portion of a parabolic curve, as viewed from above.

A highly desirable embodiment of an invention is a semiconductor body suitable as a solar collector, such as silicon.

Yet another invention hereof is a patterned semiconductor article, the article comprising: a semiconductor body having a first surface; a perimeter edge bounding the first surface; and, upon the first surface, at least one groove, having a relatively longer dimension than a perpendicular dimension, the work piece further comprising at least one alignment guide, which groove bears a metallization along substantially its entire length. The at least one groove conveniently may comprise a plurality of substantially parallel grooves and each or many may bear a metallization. Or, the at least one groove comprises a serpentine groove, that reverses direction at least one time. The body can, of course, be a solar collector.

The plurality of parallel grooves with metallization may comprise metallization fingers. In an interesting embodiment, intersecting with at least one of the fingers there is a bus wire metallization that is wider than the finger. The metallization finger may beneficially have a greater cross-sectional area where the bus wire intersects than at least one end of the metallization finger.

With this embodiment, as with others discussed above, the at least one alignment guide may comprise a lead in feature at least one end of the groove. The lead in feature can comprise a feature selected from the group consisting of: chevrons, wedges, pairs of arcs tangent to the physical work piece path and pairs of angled grooves, open triangular spaces.

The at least one alignment guide may also or alternatively comprise a restoring feature adjacent the at least one groove, typically a plurality of restoring features adjacent and along the groove.

Yet another, very important invention hereof is a method for providing a material that contains a liquid to a textured surface of a semiconductor work piece. The method comprises the steps of: providing a semiconductor work piece having a textured surface that defines a physical work piece path; providing a flexible tube having a support end and a dispensing end, the dispensing end sized and shaped to mechanically track the physical work piece path; engaging the dispensing end of the flexible tube with the physical work piece path; establishing a positive contact force between the dispensing end and the textured surface; providing material that contains liquid to the flexible tube and causing the material that contains liquid to be dispensed from the tube to the textured surface of the work piece; and causing relative motion between the dispensing end of the tube as compared to the work piece path along a physical unconstrained dispensing end path, while the material that contains liquid is dispensed onto the work piece, along the physical work piece path.

The step of causing relative motion can comprise causing such motion so that the physical unconstrained dispensing end path deviates from the physical work piece path by an error ε, with the flexibility of the tube being chosen such that despite the error ε, the dispensing end of the tube mechanically tracks the physical work piece path.

The step of establishing a positive contact force can comprise preloading the dispensing end of the flexible tube toward the textured surface by advancing the support end of the flexible tube further toward the textured surface, after contact has been made by the tube and the work piece, applying a flex to the tube.

Alternatively, or in addition, the step of establishing a positive contact force may comprise establishing a magnetic force attracting the flexible tube and the textured surface path toward each other.

In a typical embodiment, the physical work piece path comprises a groove.

In general, associated with the work piece path, there is at least one alignment guide. The at least one alignment guide may comprise one or more restoring features.

The at least one alignment guide may comprise a lead-in feature, with typical lead in features being selected from the group consisting of: a chevron, a wedge-shaped depression, a triangular depression, a pair of arcs tangent to the physical work piece path and a pair of angled grooves.

With another important form of invention hereof, the work piece further comprises an edge, toward which the work piece path extends. Covering a portion of the work piece adjacent the edge at least up to the work piece path, there may be a masking material. If so, the step of causing relative motion may comprise moving the tube support end along the work piece path, and over the masking material, further wherein the step of dispensing the material that contains liquid is conducted while the dispensing end is over the masking material so that material is dispensed onto the mask material.

It is possible to vary the speed of relative motion at one location of the work piece as compared to at another location.

It is often useful to cause the dispensing end of the tube to pass through a cleansing bath after it has passed along one work piece path and before it is caused to pass along another work piece path.

Flow of the material that contains liquid may be beneficially regulated by application of pressure

In a most typical case, at least two work pieces are provided, aligned such that a physical work piece path of each are substantially collinear, wherein the step of causing relative motion comprises causing relative motion between the support end of the tube and each of the at least two work pieces, simultaneously, and engaging the dispensing end of the flexible tube with the physical work piece path of a first of the at least two work pieces, and then another of the at least two work pieces, without significantly decelerating the dispensing tube at an end of travel adjacent the first of the work pieces and without accelerating the dispensing tube adjacent the other of the at least two work pieces.

### ASPECTS OF INVENTIONS

The following aspects of inventions hereof are intended to be described herein, and this section is to ensure that they are mentioned. They are styled as aspects, and although they appear similar to claims, they are not claims. However, at some point in the future, the applicants reserve the right to claim any and all of these aspects in this and any related applications.

A1. An apparatus for dispensing a material that contains a liquid to a textured surface of a semiconductor work piece, the apparatus comprising:

a. a work piece support, configured to support a work piece;

b. a relative motion device;

c. a flexible dispensing tube having a support end and a dispensing end, the dispensing end comprising a tracking feature, the support end coupled to the relative motion device through a tube support;

d. the relative motion device configured to cause relative motion of the dispensing end of the tube as compared to the work piece support, along a physical unconstrained dispensing end path, the flexibility of the tube being chosen such that upon engagement of the tracking feature with a physical work piece path of a textured surface of a work piece supported by the support, and actuation of the relative motion device, the dispensing end of the tube mechanically tracks the physical work piece path.

A2. The apparatus of aspect 1, the tracking feature sized and shaped to mechanically track a physical work piece path defined by a textured surface of a work piece.

A3. The apparatus of aspect 1, the tube having a non-circular cross-section at its dispensing end.

A4. The apparatus of aspect 1, further comprising, a body that is less flexible than the flexible tube, the support end of the flexible tube being secured to and hydraulically coupled to the less flexible body.

A5. The apparatus of aspect 1, the tracking feature comprising a protrusion at least one end of a cross-sectional extent of the tube.

A6. The apparatus of aspect 5, the protrusion comprising a wear resistant material.

A7. The apparatus of aspect 5, the protrusion comprising a magnetically attractive material.

A8. The apparatus of aspect 7, further comprising, a body that is attracted to the magnetically attractive material, arranged to attract the magnetically attractive material toward the support.

A9. The apparatus of aspect 5, the protrusion comprising a magnetic material holding a permanent magnetic moment.

A10. The apparatus of aspect 5, the protrusion comprising a body adhered to the flexible tube.

A11. The apparatus of aspect 5, the protrusion comprising a body integral with the flexible tube, formed at least in part from the same material as is formed the flexible tube.

A12. The apparatus of aspect 5, the flexible tube having a long axis and a lateral extent substantially perpendicular to the long axis, the tracking feature having a lateral extent that is less than a lateral extent of the tube.

A13. The apparatus of aspect 5, the physical work piece path having a characteristic minimum width, the tracking feature having a characteristic width that is less than the physical work piece path characteristic minimum width.

A14. The apparatus of aspect 5, the physical work piece path having a characteristic width, the tube having a diameter of less than about ten times the physical work piece path characteristic width.

A15. The apparatus of aspect 5, the tracking feature comprising two tracking features, each one being a protrusion at opposite ends of at least one cross-sectional extent.

A16. The apparatus of aspect 15, the tracking feature comprising four protrusions, one each at opposite ends of two orthogonal cross-sectional extents.

A17. The apparatus of aspect 1, the tracking feature comprising an extended rib substantially parallel to an axis of the flexible tube along the outside of the tube.

A18. The apparatus of aspect 17, the tracking feature comprising extended ribs along opposite sides of the tube.

A19. The apparatus of aspect 1, the dispensing end having a cross section that has a first cross-sectional extent that is larger than a cross-sectional extent that is perpendicular to the first cross-sectional extent.

A20. The apparatus of aspect 19, the larger cross-sectional extent arranged substantially perpendicular to a plane of an work piece.

A21. The apparatus of aspect 19, the flexible tube dispensing end having a cross-sectional shape that has a protrusion at one end of the first cross-sectional extent.

A22. The apparatus of aspect 1, the dispensing end having a shape selected from the group consisting of: a bevel; a main portion with a protruding portion; a circle; an ellipse, a partially flattened circle.

A23. The apparatus of claim 1, the flexibility of the flexible tube being chosen to permit the dispensing end of the tube to mechanically track a physical work piece path despite an error between the physical work piece path and the physical unconstrained dispensing end path.

A24. The apparatus of aspect 1, the flexible tube comprising a material selected from the group consisting of: a polymer, polyimide, glass, quartz, metal and stainless steel.

A25. The apparatus of aspect 1, the flexible tube comprising a coated tube.

A26. The apparatus of aspect 1, further comprising a plurality of additional flexible tubes each of which is secured to the tube support.

A27. The apparatus of aspect 26, further comprising, thermally coupled to each of the plurality of tubes, a temperature control.

A28. The apparatus of aspect 27, each temperature control comprising an independently controllable control.

A29. The apparatus of aspect 27, each temperature control comprising a heater.

A30. The apparatus of aspect 28, each temperature control comprising a light positioned to shine upon a respective tube.

A31. The apparatus of aspect 27, each tube comprising a conductive coating.

A32. The apparatus of aspect 27, a temperature control comprising a radio frequency coil.

A33. The apparatus of aspect 1, the flexible tube comprising a polyimide material.

A34. The apparatus of aspect 1, the flexible tube comprising a quartz material.

A35. The apparatus of aspect 1, the flexible tube dispensing end having a cross section that has an extent arranged along a first dimension that has a component that is substantially parallel to the direction of relative motion between the tube and the work piece, which extent is larger than a second extent of the dispensing end that is perpendicular to the first dimension.

A36. The apparatus of aspect 1, the flexibility of the flexible tube being such as to permit the dispensing end of the tube to follow any deviations in the physical work piece path from a flat plane path.

A37. The apparatus of aspect 1, further comprising a material delivery apparatus, coupled to the flexible tube, configured to deliver material that contains liquid to the flexible tube.

A38. The apparatus of aspect 37, the material delivery apparatus comprising a metering pump.

A39. The apparatus of aspect 37, the material delivery apparatus comprising a pressurized volume of such material hydraulically coupled to the support end of the dispensing tube.

A40. The apparatus of aspect 37, the work piece support comprising a fixture that maintains at least two work pieces fixed relative to each other so that a physical work piece path of each are substantially collinear.

A41. The apparatus of aspect 40, the fixture comprising a drum, with work piece locating stations around its periphery.

A42. The apparatus of aspect A1, further comprising, adjacent the work piece support, a bath of cleaning fluid.

A43. An apparatus for dispensing a material that contains liquid to a textured surface of a semiconductor work piece, the apparatus comprising a flexible tube having a support end and a dispensing end, the dispensing end comprising a mechanical tracking feature.

A44. The apparatus of aspect 43, the tracking feature sized and shaped to mechanically track a physical work piece path defined by a textured work piece surface.

A45. The apparatus of aspect 43, the tube having a non-circular cross-section at its dispensing end.

A46. The apparatus of aspect 43, further comprising a body that is less flexible than the flexible tube, the support end of the flexible tube being secured to and hydraulically coupled to the less flexible body.

A47. The apparatus of aspect 43, the tracking feature comprising a protrusion at least one end of a cross-section extent of the tube.

A48. The apparatus of aspect 47, the protrusion comprising a wear resistant material.

A49. The apparatus of aspect 47, the protrusion comprising a magnetically attractive material.

A50. The apparatus of aspect 47, the protrusion comprising a magnetic material.

A51. The apparatus of aspect 47, the protrusion comprising a body adhered to the flexible tube.

A52. The apparatus of aspect 47, the protrusion comprising a body integral with the flexible tube, formed at least in part from material that also forms the tube.

A53. The apparatus of aspect 47, the flexible tube having a long axis and a lateral extent substantially perpendicular to the lateral extent, the tracking feature having a lateral extent that is less than the lateral extent of the tube.

A54. The apparatus of aspect 47, the path having a characteristic minimum width, the tracking feature having a characteristic width dimension that is less than the physical work piece path characteristic minimum width.

A55. The apparatus of aspect 47, the physical work piece path having a characteristic width, the tube having a diameter of less than about ten times the physical work piece path characteristic width.

A56. The apparatus of aspect 47, the tracking feature comprising two tracking features, each one being a protrusion at opposite ends of the at least one cross-sectional extent.

A57. The apparatus of aspect 56, the tracking feature comprising four protrusions, one each at opposite ends of two orthogonal cross-sectional extents.

A58. The apparatus of aspect 43, the tracking feature comprising an extended rib, substantially parallel to an axis of the flexible tube along the outside of the tube.

A59. The apparatus of aspect 58, the tracking feature comprising extended ribs along opposite sides of the tube.

A60. The apparatus of aspect 43, the dispensing end having a cross section that has a first cross-sectional extent that is larger than a cross-sectional extent that is perpendicular to the first cross-sectional extent.

A61. The apparatus of aspect 60, the flexible tube dispensing end having a cross-sectional shape that has a protrusion at one end of the first cross-sectional extent.

A62. The apparatus of aspect 60, the dispensing end having a shape selected from the group consisting of: a bevel; a protruding portion; a circle; an ellipse, a partially flattened circle, a shape having a protrusion on one side.

A63. The apparatus of aspect 43, the flexibility of the flexible tube being chosen to permit the dispensing end of the tube to mechanically track a physical work piece path despite an error between a physical unconstrained dispensing end path followed by the dispensing end and the physical work piece path.

A64. The apparatus of aspect 43, the flexible tube comprising a material selected from the group consisting of: a polymer, polyimide, glass, quartz, metal, stainless steel.

A65. The apparatus of aspect 43, the flexible tube comprising a coated tube.

A66. The apparatus of aspect 43, further comprising:

a. a dispensing assembly;

b. a plurality of additional apparati as mentioned in aspect 43, each of which is secured in the dispensing assembly.

A67. The apparatus of aspect 66, further comprising, thermally coupled to each of the plurality of apparati as mentioned in aspect 101, a temperature control.

A68. The apparatus of aspect 67, each temperature control comprising an independently controllable control.

A69. The apparatus of aspect 67, each temperature control comprising a heater.

A70. The apparatus of aspect 68, each temperature control comprising a light that may be positioned to shine upon a respective tube.

A71. The apparatus of aspect 67, each tube comprising a conductive coating.

A72. The apparatus of aspect 67, a temperature control comprising a radio frequency coil.

A73. A patterned work piece upon which a material that contains a liquid is to be deposited, the work piece comprising:

a. a semiconductor body having a first surface;

b. a perimeter edge bounding the first surface;

c. upon the first surface, a physical work piece path comprising at least one groove having a relatively longer dimension than a perpendicular dimension, the work piece further comprising at least one alignment guide.

A74. The work piece of aspect 73, wherein the material that contains liquid is to be deposited by a dispensing tube, having a dispensing end, the at least one groove having a size and shape selected to mechanically track the dispensing end, and to apply a restoring force to the dispensing tube in opposition to any force that tends to disengage the dispensing end from the groove in a direction perpendicular to the long dimension of the groove.

A75. The work piece of aspect 73, the at least one groove comprising a plurality of substantially parallel grooves.

A76. The work piece of aspect 73, the at least one groove comprising a serpentine groove, that reverses direction at least one time.

A77. The work piece of aspect 76, further comprising, at least one end of the serpentine groove, a mask.

A78. The work piece of aspect 73, the at least one alignment guide comprising a lead in feature at least one end of the groove.

A79. The work piece of aspect 78, the at least one groove comprising a plurality of parallel grooves.

A80. The work piece of aspect 78, the lead in features comprising features selected from the group consisting of: an open triangular space, a chevron, a wedge, an arc tangent to the physical work piece path and a pair of angled grooves, a delta.

A81. The work piece of aspect 73, the at least one alignment guide comprising a restoring feature adjacent the physical work piece path.

A82. The work piece of aspect 81, the at least one alignment guide comprising a plurality of restoring features adjacent and along the physical work piece path.

A83. The work piece of aspect 81, the restoring features comprising features selected from the group consisting of grooves that are diagonal with the work piece path and pits arranged along a line that is diagonal with the work piece path.

A84. The work piece of aspect 73, each at least one groove having two ends, further comprising, at each such end, a mask.

A85. The work piece of aspect 73, at least one of the grooves having two ends, and having a width at each end that is less than a width at a location between the two ends.

A86. The work piece of aspect 73, at least one groove following a portion of a parabolic curve, as viewed from above.

A87. The work piece of aspect 73, the semiconductor body comprising a semiconductor suitable as a solar collector.

A88. The work piece of aspect 73, the semiconductor comprising silicon.

A89. A patterned semiconductor article, the article comprising:

a. a semiconductor body having a first surface;

b. a perimeter edge bounding the first surface;

c. upon the first surface, at least one groove, having a relatively longer dimension than a perpendicular dimension, the work piece further comprising at least one alignment guide, which groove bears a metallization along substantially its entire length.

A90. The semiconductor article of aspect 89, the at least one groove comprising a plurality of substantially parallel grooves.

A91. The semiconductor article of aspect 89, the at least one groove comprising a serpentine groove, that reverses direction at least one time.

A92. The semiconductor article of aspect 89, the at least one alignment guide comprising a lead in feature at least one end of the groove.

A93. The semiconductor article of aspect 92, the lead in feature comprising a feature selected from the group consisting of: chevrons, wedges, arcs tangent to the physical work piece path and pairs of angled grooves.

A94. The semiconductor article of aspect 89, the at least one alignment guide comprising a restoring feature adjacent the at least one groove.

A95. The semiconductor article of aspect 94, the at least one alignment guide comprising a plurality of restoring features adjacent and along the groove.

A96. The semiconductor body of aspect 90, the plurality of parallel grooves with metallization comprising metallization fingers, further comprising, intersecting with at least one of the fingers, a bus wire metallization that is wider than the finger.

A97. The semiconductor body of aspect 96, the metallization finger having a greater cross-sectional area where the bus wire intersects than at least one end of the metallization finger.

A98. The semiconductor body of aspect 89, the body comprising a solar collector.

A99. A method for providing a material that contains a liquid to a textured surface of a semiconductor work piece, the method comprising the steps of:

a. providing a semiconductor work piece having a textured surface that defines a physical work piece path;

b. providing a flexible tube having a support end and a dispensing end, the dispensing end sized and shaped to mechanically track the physical work piece path;

c. engaging the dispensing end of the flexible tube with the physical work piece path;

d. establishing a positive contact force between the dispensing end and the textured surface;

e. providing material that contains liquid to the flexible tube and causing the material that contains liquid to be dispensed from the tube to the textured surface of the work piece; and f. causing relative motion between the dispensing end of the tube as compared to the work piece path so that the dispensing end mechanically tracks the physical work piece path while the material that contains liquid is dispensed onto the work piece, along the physical work piece path.

A100. The method of aspect 99, the step of causing relative motion comprising causing the dispensing end to follow a physical unconstrained dispensing end path which deviates from the physical work piece path by an error, the flexibility of the tube being chosen such that despite the error, the dispensing end of the tube mechanically tracks the physical work piece path.

A101. The method of aspect 99, the step of establishing a positive contact force comprising preloading the dispensing end of the flexible tube toward the textured surface by advancing the support end of the flexible tube further toward the textured surface, after contact has been made by the tube and the work piece, applying a flex to the tube.

A102 The method of aspect 99, the step of establishing a positive contact force comprising establishing a magnetic force attracting the flexible tube and the textured surface path toward each other.

A103. The method of aspect 99, the physical work piece path comprising a groove.

A104 The method of aspect 99, further comprising, associated with the work piece path, at least one alignment guide.

A105. The method of aspect 104, the at least one alignment guide comprising a lead-in feature.

A106. The method of aspect 104, the at least one alignment guide comprising a restoring feature.

A107. The method of aspect 105, the lead in feature being selected from the group consisting of: a raised chevron, a wedge-shaped depression, a triangular depression, an arc tangent to the physical work piece path and a pair of angled grooves that meet.

A108. The method of aspect 99, the work piece further comprising:

a. an edge, toward which the work piece path extends;

b. covering a portion of the work piece adjacent the edge at least up to the work piece path, a masking material.

A109. The method of aspect 99, further comprising the step of varying the speed of relative motion at one location of the work piece as compared to at another location.

A110. The method of aspect 108, wherein the step of causing relative motion comprises moving the tube support end along the work piece path, and over the masking material, further wherein the step of dispensing the material that contains liquid is conducted while the dispensing end is over the masking material so that material is dispensed onto the mask material.

A111. The method of aspect 108, further comprising the step of causing the dispensing end of the tube to pass through a cleansing bath after it has passed along one work piece path and before it is caused to pass along another work piece path.

A112. The method of aspect 99, further comprising, regulating flow of the material that contains liquid by application of pressure.

A113. The method of aspect 99, further comprising the step of providing at least two work pieces, aligned such that a physical work piece path of each are substantially collinear, wherein the step of causing relative motion comprises causing relative motion between the support end of the tube and each of the at least two work pieces, simultaneously, and engaging the dispensing end of the flexible tube with the physical work piece path of a first of the at least two work pieces, and then another of the at least two work pieces, without significantly decelerating the dispensing tube at an end of travel adjacent the first of the work pieces and without accelerating the dispensing tube adjacent the other of the at least two work pieces.

A114. The method of aspect 99, the work piece path comprising a serpentine path, the step of causing relative motion comprising causing a relative motion having a substantially constant velocity magnitude.

Having described the inventions disclosed herein, what is claimed is:

1. An apparatus for dispensing a material that contains a liquid to a textured surface of a semiconductor work piece, the apparatus comprising:
a. a work piece support, configured to support a work piece;
b. a relative motion device;
c. a flexible dispensing tube having a support end and a dispensing end, the dispensing end comprising a tracking feature, the support end coupled to the relative motion device through a tube support;
d. the relative motion device configured to cause relative motion of the dispensing end of the tube as compared to the work piece support, along a physical unconstrained dispensing end path, the flexibility of the tube being chosen such that upon engagement of the tracking feature with a physical work piece path of a textured surface of a work piece supported by the support, and actuation of the relative motion device, the dispensing end of the tube mechanically tracks the physical work piece path.

2. The apparatus of claim 1, the tracking feature sized and shaped to mechanically track the physical work piece path defined by the textured surface of the work piece.

3. The apparatus of claim 1, the tracking feature comprising a protrusion at least one end of a cross-sectional extent of the tube.

4. The apparatus of claim 3, the physical work piece path having a characteristic minimum width, the tracking feature having a characteristic width that is less than the physical work piece path characteristic minimum width.

5. The apparatus of claim 3, the physical work piece path having a characteristic width, the tube having a maximum cross-sectional extent of less than about ten times the physical work piece path characteristic width.

6. The apparatus of claim 1, the flexibility of the flexible tube being chosen to permit the dispensing end of the tube to mechanically track the physical work piece path despite an error between the physical work piece path and the physical unconstrained dispensing end path.

7. The apparatus of claim 1, further comprising a plurality of additional flexible tubes each of which is secured to the tube support.

8. The apparatus of claim 1, the work piece support comprising a fixture that maintains at least two work pieces fixed relative to each other so that a physical work piece path of each are substantially collinear.

9. An apparatus for dispensing a material that contains liquid to a textured surface of a semiconductor work piece, the apparatus comprising a flexible tube having a support end and a dispensing end, the dispensing end comprising a mechanical tracking feature.

10. The apparatus of claim 9, the tracking feature sized and shaped to mechanically track a physical work piece path defined by a textured work piece surface.

11. The apparatus of claim 9, the tube having a non-circular cross-section at its dispensing end.

12. The apparatus of claim 9, the tracking feature comprising a protrusion at least one end of a cross-sectional extent of the tube.

13. The apparatus of claim 12, the protrusion comprising a wear resistant material.

14. The apparatus of claim 12, the protrusion comprising a magnetically attractive material.

15. The apparatus of claim 12, the flexible tube having a long axis and a lateral extent substantially perpendicular to the long axis, the tracking feature having a lateral extent that is less than the lateral extent of the tube.

16. The apparatus of claim 12, the tracking feature comprising two tracking features, each one being a protrusion at opposite ends of the at least one cross-sectional extent.

17. The apparatus of claim 9, the tracking feature comprising an extended rib, substantially parallel to an axis of the flexible tube along the outside of the tube.

18. The apparatus of claim 9, the flexible tube comprising a material selected from the group consisting of: a polymer, polyimide, glass, quartz, metal and stainless steel.

19. A patterned work piece upon which a material that contains a liquid is to be deposited, the work piece comprising:
a. a semiconductor body having a first surface; and
b. upon the first surface, a physical work piece path comprising at least one groove having a relatively longer dimension than a perpendicular dimension, the work piece further comprising at least one alignment guide.

20. The work piece of claim 19, the at least one groove comprising a plurality of substantially parallel grooves.

21. The work piece of claim 19, the at least one alignment guide comprising a lead in feature at least one end of the groove.

22. The work piece of claim 21, the at least one groove comprising a plurality of substantially parallel grooves.

23. The work piece of claim 21, the lead in features comprising features selected from the group consisting of: an open triangular space, a chevron, a wedge, an arc tangent to the physical work piece path and a pair of angled grooves.

24. The work piece of claim 19, the at least one alignment guide comprising a restoring feature adjacent the physical work piece path.

25. The work piece of claim 19, each at least one groove having two ends, further comprising, at least one such end, a mask.

26. A patterned semiconductor article, the article comprising:
a. a semiconductor body having a first surface; and
b. upon the first surface, at least one groove, having a relatively longer dimension than a perpendicular dimension, the work piece further comprising at least one alignment guide, which groove bears a metallization along substantially its entire length.

27. The semiconductor article of claim 26, the at least one groove comprising a plurality of substantially parallel grooves.

28. The semiconductor article of claim 26, the at least one alignment guide comprising a lead in feature at least one end of the groove.

29. The semiconductor article of claim 28, the lead in feature comprising a feature selected from the group consisting of: an open triangular space, a chevron, a wedge, an arc tangent to the physical work piece path and a pair of angled grooves.

30. The semiconductor article of claim 26, the at least one alignment guide comprising a restoring feature adjacent the at least one groove.

31. A method for providing a material that contains a liquid to a textured surface of a semiconductor work piece, the method comprising the steps of:
a. providing a semiconductor work piece having a textured surface that defines a physical work piece path;
b. providing a flexible tube having a support end and a dispensing end, the dispensing end sized and shaped to mechanically track the physical work piece path;
c. engaging the dispensing end of the flexible tube with the physical work piece path;
d. establishing a positive contact force between the dispensing end and the textured surface;
e. providing material that contains liquid to the flexible tube and causing the material that contains liquid to be dispensed from the tube to the textured surface of the work piece; and
f. causing relative motion between the dispensing end of the tube as compared to the work piece path so that the dispensing end mechanically tracks the physical work piece path while the material that contains liquid is dispensed onto the work piece, along the physical work piece path.

32. The method of claim 31, the step of causing relative motion comprising causing the dispensing end to follow a physical unconstrained dispensing end path which deviates from the physical work piece path by an error, the flexibility of the tube being chosen such that despite the error, the dispensing end of the tube mechanically tracks the physical work piece path.

33. The method of claim 31, the step of establishing a positive contact force comprising preloading the dispensing end of the flexible tube toward the textured surface by advancing the support end of the flexible tube further toward the textured surface, after contact has been made by the tube and the work piece, applying a flex to the tube.

34. The method of claim 31, the physical work piece path comprising a groove.

35. The method of claim 31, further comprising the step of causing the dispensing end of the tube to pass through a cleansing bath after it has passed along one work piece path and before it is caused to pass along another work piece path.
